(19) United States
(12) Patent Application Publication
(10) Pub. No.: US 2008/0296651 A1
(43) Pub. Date: Dec. 4, 2008

(54) SEMICONDUCTOR DEVICE

(76) Inventor: MASAAKI YOSHIDA, Hyogo (JP)

Correspondence Address: DICKSTEIN SHAPIRO LLP, 1825 EYE STREET NW, Washington, DC, 20006-5403, US

(21) Appl. No.: 12/125,699

(22) Filed: May 22, 2008

(30) Foreign Application Priority Data
May 30, 2007 (JP) 2007-143455

(51) Int. Cl. H01L 29/788

(52) U.S. Cl. 257/315; 257/E29.3

(57) ABSTRACT

A disclosed semiconductor device comprises a non-volatile memory cell including a PMOS write transistor and an NMOS read transistor. The PMOS write transistor includes a write memory gate oxide film formed on a semiconductor substrate and a write floating gate of electrically-floating polysilicon formed on the write memory gate oxide film. The NMOS read transistor includes a read memory gate oxide film formed on the semiconductor substrate and a read floating gate of electrically-floating polysilicon formed on the read memory gate oxide film. The write floating gate and the read floating gate are electrically connected to each other. The PMOS write transistor is configured to perform writing in the non-volatile memory cell, and the NMOS read transistor is configured to perform reading from the non-volatile memory cell.

### BACKGROUND OF THE INVENTION

1. Field of the Invention

The present invention relates to a semiconductor device including a non-volatile memory cell having a floating gate. Such a semiconductor device is applicable to, for example, a semiconductor device including a dividing resistance circuit, a voltage detecting circuit, or a constant voltage generating circuit. This semiconductor device may be mounted together with a circuit as a core component, such as a CPU.

2. Description of the Related Art

Non-volatile memory cells can be generally classified into two types based on the number of gates: a single-layer gate type and a double-layer gate type. For example, Japanese Patent Laid-Open Publication No. 6-85275 (corresponding to U.S. Pat. No. 5,282,161) (Patent Document 1) and Japanese Translated International Patent Application Publication No. 8-506693 (corresponding to WO/1994/000881)(Patent Document 2) disclose single-layer gate non-volatile memory cells. Japanese Examined Patent Publication No. 4-80544 (Patent Document 3) discloses a double-layer gate non-volatile memory cell.

There are products such as NAND flash memories on the market that are dedicated to provide semiconductor memories. On the other hand, there are products that are designed mainly to control other devices and use non-volatile memories for correcting characteristics of the devices to be controlled. The sales in this field are now growing.

To take an example, a driver IC for a liquid crystal display (LCD) is designed to control the LCD. Because a variation of luminance between dots due to a production variation reduces the visual quality of the display, the driver IC uses a non-volatile memory for correcting luminance of individual dots, thereby improving the quality.

To take another example, a voltage detecting IC is preferably subjected to a trimming process after being packaged. However, because a normal fuse trimming using lasers cannot be performed after packaging, a non-volatile memory is used in place of a fuse.

Non-volatile memories that are used in such cases need only a relatively small number of bits ranging from several bits to several kilobits.

For minimizing cost increase due to inclusion of a memory and achieving higher compatibility with a normal CMOS circuit, the single-layer gate type is advantageous as the structure of such non-volatile memories. This is obvious because the double-layer gate type involves more masking steps (a cause of cost increase) and has adverse effects on normal devices due to a process heat history (a cause of reduction in compatibility).

Meanwhile, downsizing of a circuit that controls reading from and writing in the non-volatile memory is demanded for the same reasons. Especially, the non-volatile memory often requires voltage as high as 15 V or greater for a write operation. Therefore, in many cases, a so-called high voltage device is separately provided for controlling the non-volatile memory. However, this results in increased cost and reduced compatibility with the CMOS circuit. There is therefore a demand for a single-layer gate non-volatile memory capable of writing at low voltage.

A related-art non-volatile memory cell that satisfies these demands is disclosed in Japanese Patent Laid-Open Publication No. 2003-168747 (Patent Document 4). The non-volatile memory cell of Patent Document 4 includes no control gate.

FIG. 17A is a plan view showing a non-volatile memory cell of a semiconductor device according to related art. FIG. 17B is a cross-sectional view taken along line X-X of FIG. 17A.

An N-well 103 is formed in a P-type semiconductor substrate. P-type diffusion layers 105, 107, and 109 are formed in the N-well 103. The P-type diffusion layers 105, 107, and 109 are spaced apart from one another. The P-type diffusion layer 107 is disposed between the P-type diffusion layers 105 and 109.

A memory gate oxide film 111 is formed on a region of the N-well 103 between the P-type diffusion layers 105 and 107. A floating gate 113 of a polysilicon film is formed on the memory gate oxide film 111. Thus a PMOS memory transistor is formed.

A selection gate oxide film 115 is formed on a region of the N-well 103 between the P-type diffusion layers 107 and 109. A selection gate 117 of a polysilicon film is formed on the selection gate oxide film 115. Thus a PMOS selection transistor is formed.

When erasing this non-volatile memory cell, i.e., when discharging electrons from the floating gate 113, the floating gate 113 is initialized to have no charges by irradiating ultraviolet rays onto the floating gate 113, for example.

When writing in the non-volatile memory cell, i.e., when injecting electrons into the floating gate 113, 5 V is applied to the N-well 103; 0 V is applied to the P-type diffusion layer 105; 5 V is applied to the P-type diffusion layer 109; and the selection gate 117 is set to a predetermined potential Von (e.g., 0 V), for example. Thus the PMOS selection transistor is turned on, and electrons are injected from the P-type diffusion layer 107 into the floating gate 113 via the memory gate oxide film 111. The injection of the electrons into the floating gate 113 reduces a threshold voltage of the PMOS memory transistor, thereby allowing higher current to flow upon reading from the non-volatile memory cell.

The non-volatile memory cell in which two P-type MOS transistors are connected in series as shown in FIGS. 17A and 17B is not only capable of performing writing at low voltage, but also is advantageous in cost and highly compatible with a normal CMOS process because a control gate (gate of a second layer) is not needed. For operating as a non-volatile memory, it is necessary to read the difference in current between the state after ultraviolet irradiation (e.g. an erased state “0”) and a state after writing (e.g. a written state “1”).

FIG. 18 shows a measurement result of the value of a drain current flowing through the PMOS memory transistor upon a read operation in a written state “1” and an erased state “0” in the non-volatile memory cell of FIGS. 17A and B. About 1000 samples of non-volatile memory cells in the written state “1” and about 1000 samples of non-volatile memory cells in the erased state “0” were prepared, and distribution of the drain current values flowing through PMOS memory transistors was examined. In FIG. 18, the vertical axis represents the number of bits, and the horizontal axis represents the drain current value (μA (microampere).

As shown in FIG. 18, it was found that the current flows both in the erased state “0” and the written state “1” in the non-volatile memory cell of FIGS. 17A and 17B. This phenomenon naturally occurs in the non-volatile memory cell of Patent Document 4, which has no control gate and is configured to control gate potential by voltage application to the drain etc., and coupling of drain-gate overlap.

That is, a problem with the non-volatile memory cell of FIGS. 17A and 17B is that, because the current flows both in the erased state “0” and the written state “1”, a consumption current always flows through the entire read circuit.

There is another problem that, because the current flows both in the erased state “0” and the written state “1”, it is difficult to design a read determination circuit. More specifically, it is difficult to increase the reading speed, and margin insufficiency easily occurs when a process variation is taken into consideration.

### SUMMARY OF THE INVENTION

In view of the forgoing, the present invention is directed to significantly improve read characteristics of a non-volatile memory cell of a semiconductor device that has a floating gate and no control gate.

In an embodiment of the present invention, there is provided a semiconductor device that comprises a non-volatile memory cell including a PMOS write transistor and an NMOS read transistor; wherein the PMOS write transistor includes a write memory gate oxide film formed on a semiconductor substrate and a write floating gate of electrically-floating polysilicon formed on the write memory gate oxide film; wherein the NMOS read transistor includes a read memory gate oxide film formed on the semiconductor substrate and a read floating gate of electrically-floating polysilicon formed on the read memory gate oxide film; wherein the write floating gate and the read floating gate are electrically connected to each other; and wherein the PMOS write transistor is configured to perform writing in the non-volatile memory cell, and the NMOS read transistor is configured to perform reading from the non-volatile memory cell.

In this specification and the appended claims, a PMOS transistor refers to a P-channel MOS transistor, and an NMOS transistor refers to an N-channel MOS transistor.

In the semiconductor device of the present invention, a write operation in a PMOS write transistor is an injection of electrons into a write floating gate. When electrons are injected into the write floating gate, electrons are injected into the read floating gate of the NMOS read transistor as well. If a written state “1” is read using the PMOS write transistor, current flows even in the written state “1” as shown in FIG. 18. On the other hand, if the NMOS read transistor is used for reading, because a threshold voltage Vth of the NMOS read transistor is increased by the injection of electrons, no current flows in the written state “1”. In an erased state “0” after ultraviolet irradiation, current flows through the NMOS read transistor.

According to the above-described embodiment, the non-volatile memory cell does not include a control gate (a gate of the second layer), and therefore is advantageous in cost and highly compatible with a normal CMOS process.

Furthermore, because writing is performed using the PMOS write transistor, it is possible to write at low voltage.

Furthermore, because reading is performed using the NMOS read transistor, it is possible to create a condition in which current flows in the erased state “0” and a condition in which no current flows in the written state “1”, thereby allowing simplifying a read circuit, reducing current consumption, and improving the reading speed.

It is know that, in non-volatile memories, charges of holes or electrons that are injected by a write operation leak out more or less. In the case of relate-art techniques that perform reading by using a PMOS transistor as illustrated in FIGS. 17A, 17B, and FIG. 18, the current value does not change with time in the erased state “0” because no charges are stored in the floating gate. However, in the written state “1”, charges leak out immediately after a write operation, and therefore the difference in the current value between the state “0” and the state “1” decreases with time, resulting in reduced read characteristics.

On the other hand, in the non-volatile memory cell of the semiconductor device of the above-descried embodiment of the present invention, because no current flows through the NMOS read transistor in the written state “1” in which charges (in above-descried embodiment, electrons) are injected, reduction in characteristics due to some leakage of charges does not occur. That is, the characteristics after writing are maintained, thereby preventing reduction in the read reliability for a long period of time.

In the semiconductor device of the above-described embodiment, the write floating gate and the read floating gate may be formed of a single continuous polysilicon pattern.

According to this configuration, because the write floating gate and the read floating gate can be electrically connected to each other without drawing out the potential of the write floating gate and the read floating gate to a metal interconnect, there is no need to form contacts on the write floating gate and the read floating gate. Therefore, the plane area of the non-volatile memory cell can be reduced compared with the case where the potential of the write floating gate and the read floating gate is drawn out to a metal interconnect.

In the semiconductor device of the above-described embodiment, the non-volatile memory cell may further include a PMOS selection transistor connected in series to the PMOS write transistor and an NMOS selection transistor connected in series to the NMOS read transistor; the PMOS selection transistor may include a PMOS selection gate oxide film formed on the semiconductor substrate and a PMOS selection gate of polysilicon formed on the PMOS selection gate oxide film; the NMOS selection transistor may include an NMOS selection gate oxide film formed on the semiconductor substrate and an NMOS selection gate of polysilicon formed on the NMOS selection gate oxide film; and the PMOS selection gate and the NMOS selection gate may be electrically connected to each other.

According to this configuration, plural non-volatile memory cells can easily be arranged in an array structure.

In the semiconductor device of the above-described embodiment, the PMOS selection gate and the NMOS selection gate may be formed of a single continuous polysilicon pattern.

According to this configuration, because the PMOS selection gate and the NMOS selection gate can be electrically connected to each other without drawing out the potential of the PMOS selection gate and the NMOS selection gate to a metal interconnect, there is no need to form contacts on the PMOS selection gate and the NMOS selection gate for connection between them. Therefore, the plane area of the non-volatile memory cell can be reduced compared with the case where such contacts are formed.

In the semiconductor device of the above-described embodiment, the write memory gate oxide film, the read memory gate oxide film, the PMOS selection gate oxide film, and the NMOS selection gate oxide film may have an equal thickness.

According to this configuration, these gate oxide films can be formed all at once. Therefore, the number of manufacturing steps can be reduced compared with the case where these gate oxide films are formed in separate steps.

In the semiconductor device of the above-described embodiment, the write floating gate, the read floating gate, the PMOS selection gate, and the NMOS selection gate may have an equal impurity concentration in polysilicon.

According to this configuration, these gates can be formed all at once. Therefore, the number of manufacturing steps can be reduced compared with the case where these gates are formed in separate steps.

In the case where the semiconductor device of the above-described embodiment further comprises a peripheral circuit transistor formed of a MOS transistor that includes a peripheral circuit gate oxide film formed on the semiconductor substrate and a peripheral circuit gate of polysilicon formed on the peripheral circuit gate oxide film, suppose that the PMOS write transistor, the NMOS read transistor, and the peripheral circuit transistor have gate oxide films of the same thickness, For instance, if the gate oxide film of the peripheral circuit oxide film have a sub half level thickness, for example, a 7.5 nm (nanometers) thickness, the write memory gate oxide film and the read memory oxide film have a 7.5 nm thickness as well. In this case, according to the study of the inventor of this invention, Vpp needs to be in the range of 6-7 V or greater to achieve good write characteristics.

However, upon writing into the non-volatile memory cell, it is necessary to apply a voltage in the range of, for example, 6-7 V or greater to the peripheral circuit transistor as well which applies Vpp to the non-volatile memory cell. In this case, an electric field close to 10 MV/cm (megavolt/centimeter) is applied to the peripheral circuit transistor gate oxide film having a small thickness of 7.5 nm. This may damage the peripheral circuit gate oxide film and may result in reduction in production yield and reliability of the semiconductor device.

According to the study of the inventor of this invention, the snapback voltage of the NMOS transistor having the 7.5 nm thick gate oxide film is in the range of 6-7 V, which is about the same as Vpp, and therefore the risk of damaging the peripheral circuit due to write operations is high. This may also result in reduction in production yield and reliability of the semiconductor device.

In order to overcome such problems, the gate oxide films of the PMOS write transistor, the NMOS read transistor, and the peripheral circuit transistor may be formed to have a half level thickness, for example, about 13.5 nm thickness. However, as the thickness of the gate oxide films is increased, the write voltage Vpp is increased, so that it is not possible to solve all the problems with the sub half level. That is, if the gate oxide films have about 13.5 nm thickness and VPP is in the range of 6-7 V, although the peripheral circuit gate oxide film can be prevented from being damaged, it may be impossible to achieve good write characteristics due to the thickness of the write memory gate oxide film being increased to 13.5 nm.

In the above-described embodiment, the semiconductor device may further comprise a peripheral circuit transistor formed of a MOS transistor that includes a peripheral circuit gate oxide film formed on the semiconductor substrate and a peripheral circuit gate of polysilicon formed on the peripheral circuit gate oxide film, wherein the thickness of the write memory gate oxide film is less than the thickness of the peripheral circuit gate oxide film.

According to this configuration, the peripheral circuit gate oxide film has a greater thickness to not be damaged upon writing in the memory cell, while the write memory gate oxide film has a reduced thickness to improve the writing characteristics of the non-volatile memory cell. It is therefore possible to properly write in the non-volatile memory cell while preventing the peripheral circuit gate oxide film from being damaged and preventing occurrence of snapback breakdown.

The semiconductor device of the above-described embodiment may further comprise a peripheral circuit transistor formed of a MOS transistor that includes a peripheral circuit gate oxide film formed on the semiconductor substrate and a peripheral circuit gate of polysilicon formed on the peripheral circuit gate oxide film, wherein impurity concentrations in polysilicon in the write floating gate and the read floating gate are lower than an impurity concentration in polysilicon in the peripheral circuit gate.

According to this configuration, for example, when the substantial impurity concentration is lower than 1.0×10²⁰ atoms/cm³, the charge holding characteristics of the write floating gate and the read floating gate can be improved. Further, because the impurity concentration in polysilicon in the peripheral circuit gate can be increased regardless of the impurity concentration of the write floating gate and the read floating gate, it is possible to sufficiently reduce the resistance of the peripheral circuit gate, thereby preventing reduction in the operating speed of the peripheral circuit transistor. In this specification, the substantial impurity concentration in polysilicon indicates the concentration of P-type impurities or N-type impurities that contribute to transfer of charges.

The semiconductor device of the above-described embodiment may further comprise a peripheral circuit transistor formed of a MOS transistor that includes a peripheral circuit gate oxide film formed on the semiconductor substrate and a peripheral circuit gate of polysilicon formed on the peripheral circuit gate oxide film, wherein the thickness of the write memory gate oxide film is less than the thickness of the peripheral circuit gate oxide film, and wherein thicknesses of the PMOS selection gate oxide film and the NMOS selection gate oxide film are the same as the thickness of the peripheral circuit gate oxide film.

According to this configuration, the PMOS selection gate oxide film, the NMOS selection gate oxide film, and the peripheral circuit gate oxide film can be formed all at once. Therefore, the number of manufacturing steps can be reduced compared with the case where these gate oxide films are formed in separate steps. Furthermore, because the PMOS selection gate oxide film and the NMOS selection gate oxide film can have greater thickness compared with the case where they have the same thickness as the write memory gate oxide film, it is possible to enhance pressure tightness of the PMOS selection gate oxide film and the NMOS selection gate oxide film.

The semiconductor device of the above-described embodiment may further comprise a peripheral circuit transistor formed of a MOS transistor that includes a peripheral circuit gate oxide film formed on the semiconductor substrate and a peripheral circuit gate of polysilicon formed on the peripheral circuit gate oxide film; wherein impurity concentrations in polysilicon in the write floating gate and the read floating gate are lower than an impurity concentration in polysilicon in the peripheral circuit gate; and wherein impurity concentrations in polysilicon in the PMOS selection gate and the NMOS selection gate are the same as the impurity concentration in polysilicon in the peripheral circuit gate.

According to this configuration, the PMOS selection gate, the NMOS selection gate, and the peripheral circuit gate can be formed all at once. Therefore, the number of manufacturing steps can be reduced compared with the case where these gates are formed in separate steps. With this configuration, because the PMOS selection gate, the NMOS selection gate, and the peripheral circuit gate can have higher impurity concentration in polysilicon than the write floating gate and the read floating gate, it is possible to sufficiently reduce the resistance of the PMOS selection gate, the NMOS selection gate, and the peripheral circuit gate, thereby preventing reduction in the operating speed of the PMOS selection transistor, the NMOS selection transistor, and the peripheral circuit transistor.

The semiconductor device of the above-described embodiment may further comprise an NMOS peripheral circuit transistor formed of a MOS transistor that includes an NMOS peripheral circuit gate oxide film formed on the semiconductor substrate and a peripheral circuit gate of polysilicon formed on the NMOS peripheral circuit gate oxide film, wherein a channel of the NMOS peripheral circuit transistor is doped with P-type impurities, and wherein a channel of the NMOS read transistor is not doped with P-type impurities.

A normal CMOS process, which forms a PMOS transistor and an NMOS transistor, often includes a step of doping a channel of the NMOS transistor with P-type impurities such as boron, thereby increasing a threshold voltage Vth of the NMOS transistor.

However, it is preferable for the NMOS read transistor of the non-volatile memory cell of the semiconductor device of the above-described embodiment to have a low threshold voltage Vth to cause current to flow in an erased state “0”.

According to the above-described configuration, the NMOS read transistor can have a lower threshold voltage to allow higher current flow through the NMOS read transistor when the non-volatile memory cell is in the erased state “0”, thereby improving read characteristics. Not performing channel doping in the NMOS read transistor, which is performed in a normal CMOS process, does not increase the number of manufacturing steps and brings no disadvantage in cost.

In the semiconductor device of the above-described embodiment, the NMOS read transistor may be in a depletion state in an erased state in which electrons are not injected in the write floating gate and the read floating gate.

According to this configuration, it is possible to allow higher current to flow through the NMOS read transistor when the non-volatile memory cell is in the erased state “0”, thereby further increasing the read characteristics.

Phosphorous or arsenic may be doped in the channel of the NMOS read transistor to have the NMOS read transistor in a depletion state.

### BRIEF DESCRIPTION OF THE DRAWINGS

FIG. 1A is a plan view showing a non-volatile memory cell according to an embodiment of the present invention;

FIG. 1B is a cross-sectional view taken along line A-A of FIG. 1A;

FIG. 1C is a cross-sectional view taken along line B-B of FIG. 1A;

FIG. 2 is a graph showing a measurement result of the value of a drain current flowing through an NMOS read transistor upon a read operation in a written state “1” and an erased state “0”, wherein the vertical axis represents the number of bits and the horizontal axis represent the drain current value (μA).

FIG. 3A is a plan view showing a non-volatile memory cell according to another embodiment of the present invention;

FIG. 3B is a cross-sectional view taken along line A-A of FIG. 3A;

FIG. 3C is a cross-sectional view taken along line B-B of FIG. 3A;

FIG. 4A is a plan view showing a non-volatile memory cell according to a further embodiment of the present invention;

FIG. 4B is a cross-sectional view taken along line A-A of FIG. 4A;

FIG. 4C is a cross-sectional view taken along line B-B of FIG. 4A;

FIG. 4D is a plan view showing peripheral circuit transistors;

FIG. 4E is a cross-sectional view taken along line C-C of FIG. 4D;

FIG. 4F is a cross-sectional view taken along line D-D of FIG. 4D;

FIG. 5A is a plan view showing a non-volatile memory cell according to still another embodiment of the present invention;

FIG. 5B is a cross-sectional view taken along line A-A of FIG. 5A;

FIG. 5C is a cross-sectional view taken along line B-B of FIG. 5A;

FIG. 5D is a plan view showing peripheral circuit transistors;

FIG. 5E is a cross-sectional view taken along line C-C of FIG. 5D;

FIG. 5F is a cross-sectional view taken along line D-D of FIG. 5D;

FIG. 6A is a plan view showing a non-volatile memory cell according to still another embodiment of the present invention;

FIG. 6B is a cross-sectional view taken along line A-A of FIG. 6A;

FIG. 6C is a cross-sectional view taken along line B-B of FIG. 6A;

FIG. 6D is a plan view showing peripheral circuit transistors;

FIG. 6E is a cross-sectional view taken along line C-C of FIG. 6D;

FIG. 6F is a cross-sectional view taken along line D-D of FIG. 6D;

FIG. 7 is a graph showing a measurement result of charge holding characteristics of a related-art non-volatile memory cell;

FIG. 8A is a plan view showing a non-volatile memory cell according to still another embodiment of the present invention;

FIG. 8B is a cross-sectional view taken along line A-A of FIG. 8A;

FIG. 8C is a cross-sectional view taken along line B-B of FIG. 8A;

FIG. 9A is a plan view showing a non-volatile memory cell according to still another embodiment of the present invention;

FIG. 9B is a cross-sectional view taken along line A-A of FIG. 9A;

FIG. 9C is a cross-sectional view taken along line B-B of FIG. 9A;

FIG. 10A is a plan view showing a non-volatile memory cell according to still another embodiment of the present invention;

FIG. 10B is a cross-sectional view taken along line A-A of FIG. 10A;

FIG. 10C is a cross-sectional view taken along line B-B of FIG. 10A;

FIG. 11A is a plan view showing a non-volatile memory cell according to still another embodiment of the present invention;

FIG. 11B is a cross-sectional view taken along line A-A of FIG. 11A;

FIG. 11C is a cross-sectional view taken along line B-B of FIG. 11A;

FIG. 12A is a plan view showing a non-volatile memory cell according to still another embodiment of the present invention;

FIG. 12B is a cross-sectional view taken along line A-A of FIG. 12A;

FIG. 12C is a cross-sectional view taken along line B-B of FIG. 12A;

FIG. 13A is a plan view showing a non-volatile memory cell according to still another embodiment of the present invention;

FIG. 13B is a cross-sectional view taken along line A-A of FIG. 13A;

FIG. 13C is a cross-sectional view taken along line B-B of FIG. 13A;

FIG. 13D is a plan view showing peripheral circuit transistors;

FIG. 13E is a cross-sectional view taken along line C-C of FIG. 13D;

FIG. 13F is a cross-sectional view taken along line D-D of FIG. 13D;

FIG. 14A is a plan view showing a non-volatile memory cell according to still another embodiment of the present invention;

FIG. 14B is a cross-sectional view taken along line A-A of FIG. 14A;

FIG. 14C is a cross-sectional view taken along line B-B of FIG. 14A;

FIG. 14D is a plan view showing peripheral circuit transistors;

FIG. 14E is a cross-sectional view taken along line C-C of FIG. 14D;

FIG. 14F is a cross-sectional view taken along line D-D of FIG. 14D;

FIG. 15A is a plan view showing a non-volatile memory cell according to still another embodiment of the present invention;

FIG. 15B is a cross-sectional view taken along line A-A of FIG. 15A;

FIG. 15C is a cross-sectional view taken along line B-B of FIG. 15A;

FIG. 15D is a plan view showing peripheral circuit transistors;

FIG. 15E is a cross-sectional view taken along line C-C of FIG. 15D;

FIG. 15F is a cross-sectional view taken along line D-D of FIG. 15D;

FIG. 16A is a plan view showing a non-volatile memory cell according to still another embodiment of the present invention;

FIG. 16B is a cross-sectional view taken along line A-A of FIG. 16A;

FIG. 16C is a cross-sectional view taken along line B-B of FIG. 16A;

FIG. 16D is a plan view showing peripheral circuit transistors;

FIG. 16E is a cross-sectional, view taken along line C-C of FIG. 16D;

FIG. 16F is a cross-sectional view taken along line D-D of FIG. 16D;

FIG. 17A is a plan view showing a non-volatile memory cell of a semiconductor device according to related art;

FIG. 17B is a cross-sectional view taken along line X-X of FIG. 17A; and

FIG. 18 is a graph showing a measurement result of the value of a drain current flowing through a PMOS memory transistor upon a read operation in a written state “1” and an erased state “0” in the non-volatile memory of the semiconductor device according to the related-art, wherein the vertical axis represents the number of bits and the horizontal axis represent the drain current value (μA (microampere)).

### DETAILED DESCRIPTION OF THE PREFERRED EMBODIMENT

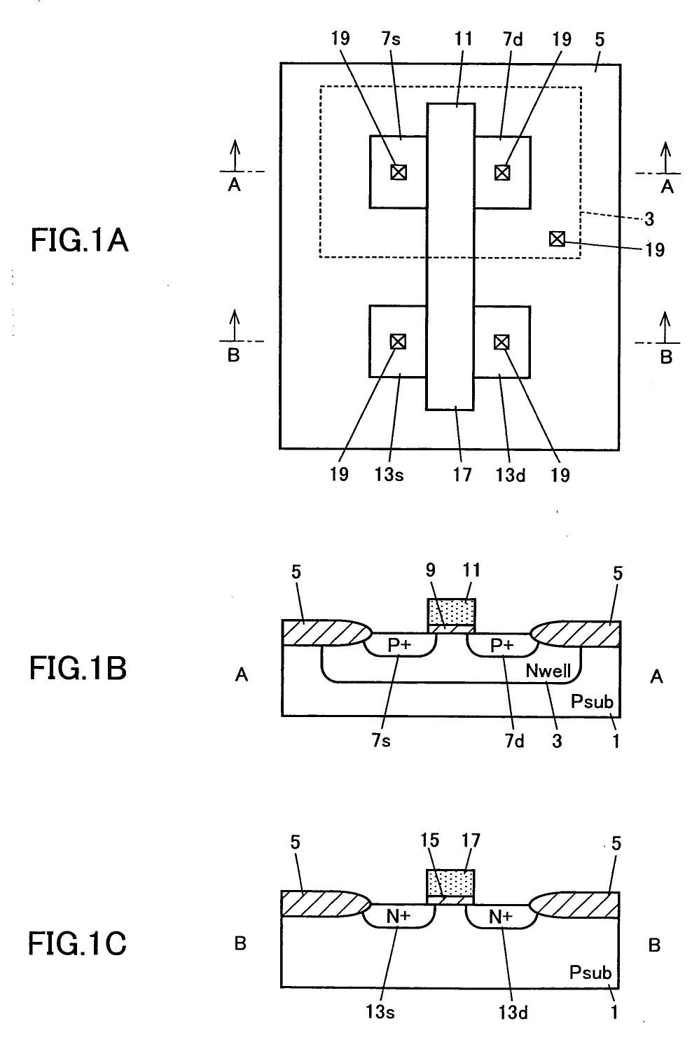

FIG. 1A is a plan view showing a non-volatile memory cell according to an embodiment of the present invention. FIG. 1B is a cross-sectional view taken along line A-A of FIG. 1A. FIG. 1C is a cross-sectional view taken along line B-B of FIG. 1A. This embodiment is described below with reference to FIGS. 1A-1C.

In this embodiment, the non-volatile memory cell includes a PMOS write transistor and an NMOS read transistor.

For example, an N-well 3 is formed in a predetermined region of a P-type semiconductor substrate 1. A field oxide film 5 of e.g., 300-700 nm thickness (in this example, 400 nm thickness) for device isolation is formed on the surface of the P-type semiconductor substrate 1. The field oxide film 5 includes openings defining a PMOS write transistor region and an NMOS read transistor region.

In a region surrounded by the field oxide film 5 as the PMOS write transistor region, a P-type source 7s and a P-type drain 7d formed of P-type diffusion layers are disposed spaced apart from each other at the surface of the N-well 3. A write memory gate oxide film 9 is formed on the N-well 3 between the P-type source 7s and the P-type drain 7d. A write floating gate 11 of polysilicon is formed on the write memory gate oxide film 9. The write memory gate oxide film 9 and the write floating gate 11 partially overlap the P-type source 7s and the P-type drain 7d when viewed from the top. The PMOS write transistor is formed in this way. A threshold voltage Vth of the PMOS write transistor is set to be in the range, for example, about 0.6-0.9 V absolute value by doping a channel with P-type impurities.

In a region surrounded by the field oxide film 5 as the NMOS read transistor region, an N-type source 13s and an N-type drain 13d formed of N-type diffusion layers are disposed spaced apart from each other at the surface of the P-type semiconductor substrate 1. In this and subsequent embodiments, a P-well may be formed at the surface of the P-type semiconductor substrate 1 in the NMOS transistor region. A read memory gate oxide film 15 is formed on the P-type semiconductor substrate 1 between the N-type source 13s and the N-type drain 13d. A read floating gate 17 of polysilicon is formed on the read memory gate oxide film 15. The read memory gate oxide film 15 and the read floating gate 17 partially overlap the N-type source 13s and the N-type drain 13d when viewed from the top. The NMOS read transistor is formed in this way. A threshold voltage Vth of the NMOS transistor is set to be in the range, for example, about 0.6-0.9 V in the absolute value by doping a channel with P-type impurities.

The write memory gate oxide film 9 and the read memory gate oxide film 15 are formed all at once, and their thickness is, for example, in the range 7.5-15.0 nm (in this example, 13.5 nm).

The P-type source 7s, the P-type drain 7d, the N-type source 13s, and the N-type drain 13d are connected to corresponding contacts 19. The field oxide film 5 further includes an opening for obtaining a potential of the N-well 3, through which opening a corresponding contact 19 is connected to the N-well 3.

The write floating gate 11 and the read floating gate 17 are formed of a single electrically-floating continuous polysilicon pattern extending on the field oxide film 5. The thickness of the write floating gate 11 and the read floating gate 17 is, e.g., 250-450 nm (in this example, 350 nm). N-type impurities such as phosphorous are implanted in the write floating gate 11 and the read floating gate 17. The substantial concentration of phosphorous is in the range, for example, from 7.0×10¹⁸ to 5.0×10¹⁹ atoms/cm³.

In the non-volatile memory cell of this embodiment, to establish an erased state “0”, erasure using ultraviolet rays is performed on the PMOS write transistor and the NMOS read transistor, thereby removing charges from the write floating gate 11 and the read floating gate 17.

To establish a written state “1”, 0 V is applied to the P-type drain 7d of the PMOS write transistor, and Vpp (e.g., 7 V) is applied to the P-type source 7s and the N-well 3 for a period of time ranging from several microseconds to several hundred microseconds. Thus electrons are injected into the write floating gate 11. At this point, electrons are also injected into the read floating gate 17 via the write floating gate 11, so that the threshold voltage Vth of the NMOS read transistor is increased to, e.g., 3-5 V, compared with the erased state “0”.

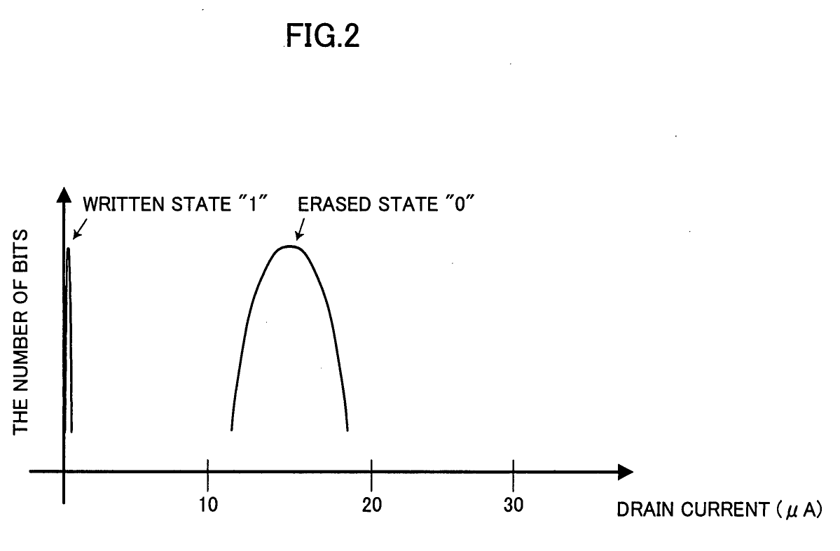

FIG. 2 shows a measurement result of the value of a drain current flowing through the NMOS read transistor upon a read operation in the written state “1” and the erased state “0”. About 1000 samples of non-volatile memory cells in the written state “1” and about 1000 samples of non-volatile memory cells in the erased state “0” were prepared, and distribution of the drain current values flowing through NMOS read transistors was examined. In FIG. 2, the vertical axis represents the number of bits, and the horizontal axis represents the drain current value (μA). For reading from the non-volatile memory cells, 2 V and 0 V were applied to the N-type drain 13d and the N-type source 13s, respectively, of the NMOS read transistor.

In the written state “1”, because the threshold voltage of the NMOS read transistor is in the range about 3-5 V due to injection of the write floating gate 11 and the read floating gate 17, very little current in a range of several picoamperes through several hundred picoamperes flows through the NMOS read transistor.

In the erased state “0”, because the threshold voltage of the NMOS read transistor is in the range about 0.6-0.9 V, a current of 10-20 μA flows through the NMOS read transistor. In this way, it is possible to read out information stored in the non-volatile memory cell by applying appropriate voltages to the N-type drain 13d and the N-type source 13s of the NMOS read transistor.

Unlike a double gate type non-volatile memory cell, the non-volatile memory cell of this embodiment does not include a control gate (a gate of the second layer), and therefore is advantageous in cost and highly compatible with a normal CMOS process.

Furthermore, because writing is performed using the PMOS write transistor, it is possible to write at a voltage as low as about 7-8 V, for example.

Furthermore, because reading is performed using the NMOS read transistor, it is possible to create a condition in which current flows in the erased state “0” and a condition in which no current flows in the written state “1”, thereby allowing simplifying a read circuit, reducing current consumption, and improving the reading speed.

Furthermore, because no current flows through the NMOS read transistor in the written state “1” in which electrons are injected, current does not flow even with some leakage of charges until the voltage reaches a read threshold voltage Vth (in this example, about 0.5-1.0 V) for reading, thereby preventing reduction in the characteristics. Thus the characteristics after writing are maintained, thereby preventing reduction in the read reliability for a long period of time.

Although the channel of the NMOS read transistor is doped with P-type impurities in this embodiment, the channel of the NMOS read transistor does not have to be doped with P-type impurities. In the case where channel doping with P-type impurities is not be applied to the NMOS read transistor, the threshold voltage Vth of the NMOS read transistor can be reduced, for example, to about 0 V, compared with the case where channel doping with P-type impurities is applied. This configuration can increase current flowing through the NMOS read transistor in the erased state “1” during reading, thereby improving the read characteristics of the non-volatile memory cell.

The channel of the NMOS read transistor may be doped with N-type impurities such as phosphorous and arsenic such that the NMOS read transistor is in a depletion state in which the threshold voltage Vth is, e.g., in the range from −0.8 to −0.3 V, when in the erased state “0”. This configuration can further increase current flowing through the NMOS read transistor in the erased state “0” during reading, thereby improving the read characteristics of the non-volatile memory cell.

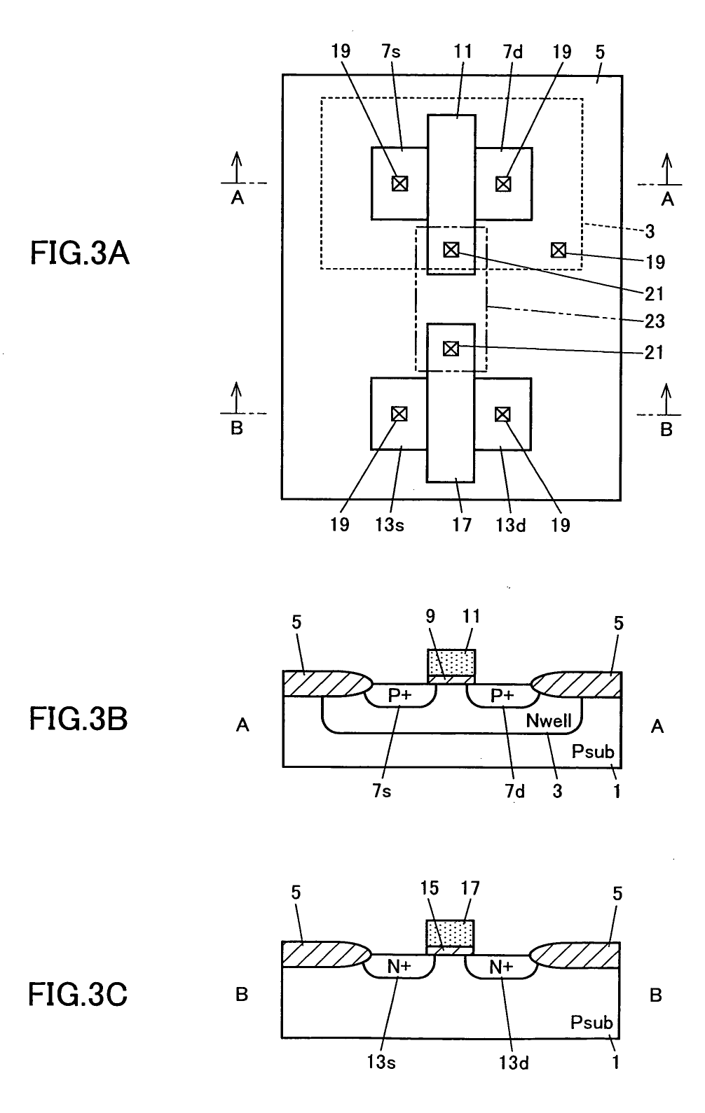

FIG. 3A is a plan view showing a non-volatile memory cell according to another embodiment of the present invention. FIG. 3B is a cross-sectional view taken along line A-A of FIG. 3A. FIG. 3C is a cross-sectional view taken along line B-B of FIG. 3A. In FIGS. 3A-3C, elements having the same functions as the elements in FIGS. 1A-1C are denoted by the same reference numerals. This embodiment is described below with reference to FIGS. 3A-3C.

The non-volatile memory cell of this embodiment is different from the non-volatile memory cell of FIGS. 1A-1C in that a write floating gate 11 and read floating gate 17 are formed of separate polysilicon patterns and are disposed spaced apart from each other. The write floating gate 11 and the read floating gate 17 are electrically connected to each other via corresponding contacts 21, 21 and a metal interconnect 23.

In this way, even if the write floating gate 11 and the read floating gate 17 are not formed of a single continuous polysilicon pattern, if the write floating gate 11 and the read floating gate 17 are electrically connected to each other, the same operation and effects as those of the non-volatile memory cell of FIGS. 1A-1C can be achieved.

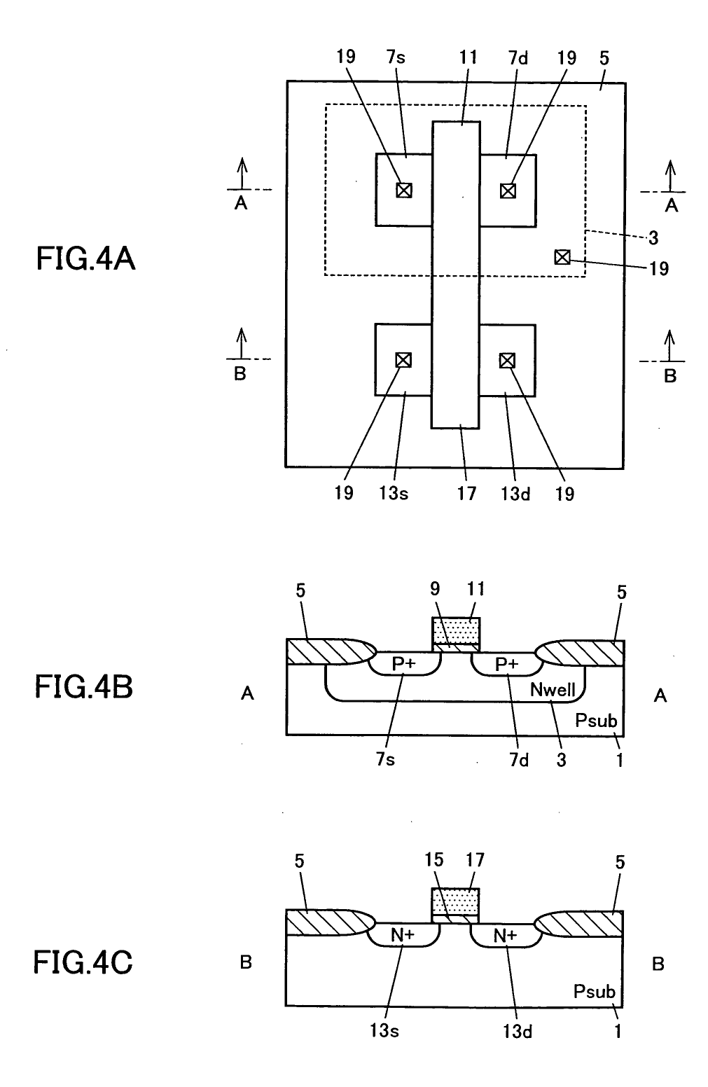

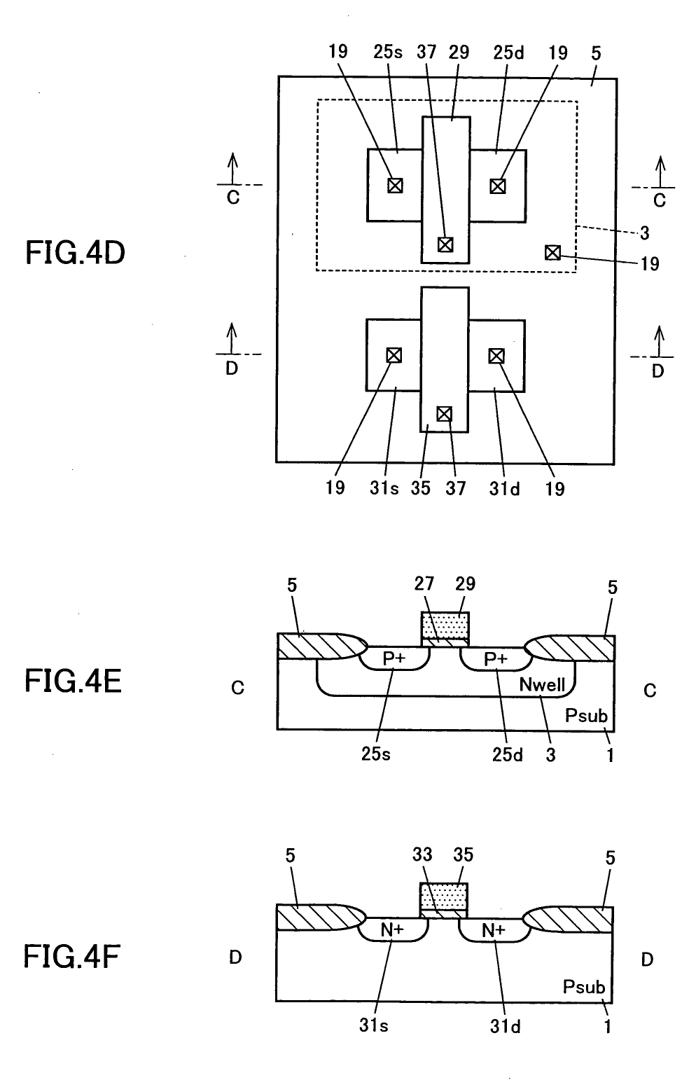

FIG. 4A is a plan view showing a non-volatile memory cell according to a further embodiment of the present invention. FIG. 4B is a cross-sectional view taken along line A-A of FIG. 4A. FIG. 4C is a cross-sectional view taken along line B-B of FIG. 4A. FIG. 4D is a plan view showing peripheral circuit transistors. FIG. 4E is a cross-sectional view taken along line C-C of FIG. 4D. FIG. 4F is a cross-sectional view taken along line D-D of FIG. 4D. In FIGS. 4A-4F, elements having the same functions as the elements in FIGS. 1A-1C are denoted by the same reference numerals. This embodiment is described below with reference to FIGS. 4A-4F.

In this embodiment, a PMOS peripheral circuit transistor and an NMOS peripheral circuit transistor are disposed in positions different from the position of a non-volatile memory cell on a P-type semiconductor substrate 1. A field oxide film 5 includes not only openings defining a PMOS write transistor region and a NMOS read transistor region but also openings defining a PMOS peripheral circuit transistor region and an NMOS peripheral circuit transistor region.

In a region surrounded by the field oxide film 5 as the PMOS peripheral circuit transistor region, a P-type source 25s and a P-type drain 25d formed of P-type diffusion layers are disposed spaced apart from each other at the surface of an N-well 3. A peripheral circuit gate oxide film 27 is formed on the N-well 3 between the P-type source 25s and the P-type drain 25d. A peripheral circuit gate 29 of polysilicon is formed on the peripheral circuit gate oxide film 27. The peripheral circuit gate oxide film 27 and the peripheral circuit gate 29 partially overlap the P-type source 25s and the P-type drain 25d when viewed from the top. The PMOS peripheral circuit transistor is formed in this way. A threshold voltage Vth of the PMOS peripheral circuit is set to be in the range, for example, about 0.6-0.9 V absolute value by doping a channel with P-type impurities.

In a region surrounded by the field oxide film 5 as the NMOS peripheral circuit transistor region, an N-type source 31s and an N-type drain 31d formed of N-type diffusion layers are disposed spaced apart from each other at the surface of the P-type semiconductor substrate 1. A peripheral circuit gate oxide film 33 is formed on the P-type semiconductor substrate 1 between the N-type source 31s and the N-type drain 31d. A peripheral circuit gate 35 of polysilicon is formed on the peripheral circuit gate oxide film 33. The peripheral circuit gate oxide film 33 and the peripheral circuit gate 35 partially overlap the N-type source 31s and the N-type drain 31d when viewed from the top. The NMOS peripheral circuit transistor is formed in this way. A threshold voltage Vth of the NMOS peripheral circuit is set to be in the range, for example, about 0.6-0.9 V absolute value by doping a channel with P-type impurities.

The write memory gate oxide film 9, the read memory gate oxide film 15, and the peripheral circuit gate oxide films 27, 33 are formed all at once, and their thickness is, for example, in the range 7.5-15.0 nm (in this example, 13.5 nm).

The write floating gate 11, the read floating gate 17, and the peripheral circuit gates 29, 35 are formed all at once, and their thickness is, for example, in the range 250-450 nm (in this example, 350 nm). N-type impurities such as phosphorous are implanted in the gates 11, 17, 29 and 35. The substantial concentration of phosphorous is in the range, for example, from 7.0×10¹⁸ to 5.0×10¹⁹ atoms/cm³.

The P-type source 7s, the P-type drain 7d, the N-type source 13s, the N-type drain 13d, the P-type source 25s, the P-type drain 25d, the N-type source 31s, and the N-type drain 31d are connected to corresponding contacts 19.

The field oxide film 5 further includes an opening for obtaining a potential of the N-well 3, through which opening a corresponding contact 19 is connected to the N-well 3.

The peripheral circuit gates 29, 35 are connected to corresponding contacts 37.

In this embodiment, the write memory gate oxide film 9, the read memory gate oxide film 15, and the peripheral circuit gate oxide films 27, 33 are formed all at once. Therefore, the number of manufacturing steps can be reduced compared with the case where these gate oxide films are formed in separate steps.

Further, the write floating gate 11, the read floating gate 17, and the peripheral circuit gates 29, 35 are formed all at once. Therefore, the number of manufacturing steps can be reduced compared with the case where these gates are formed in separate steps.

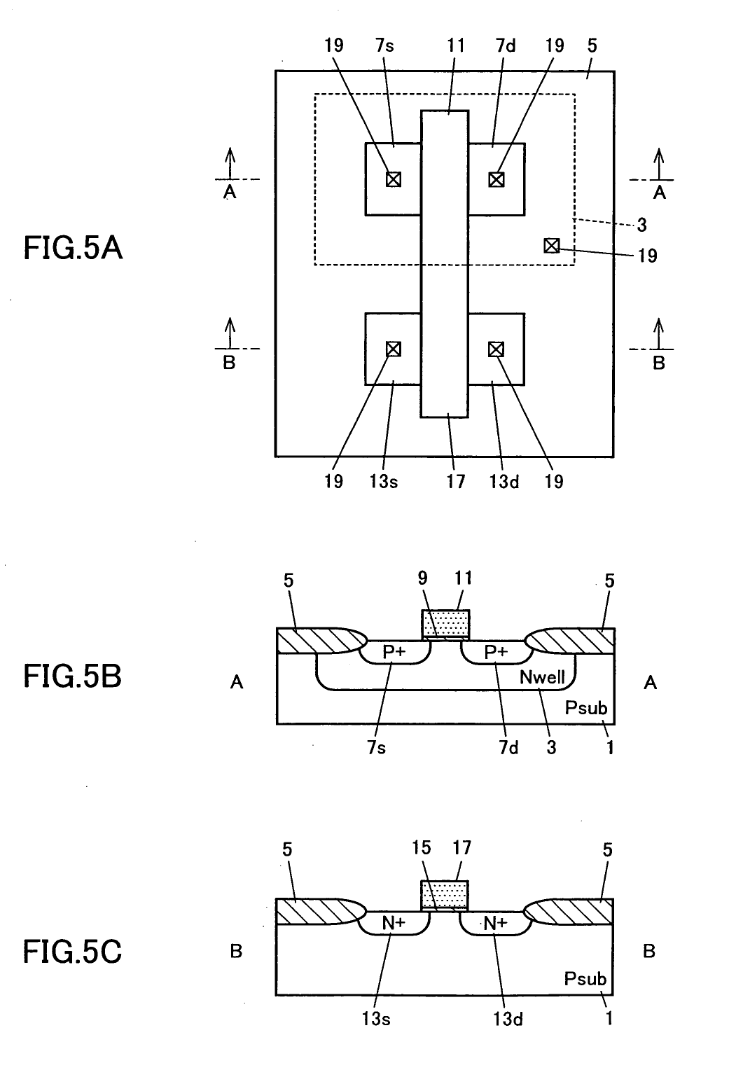

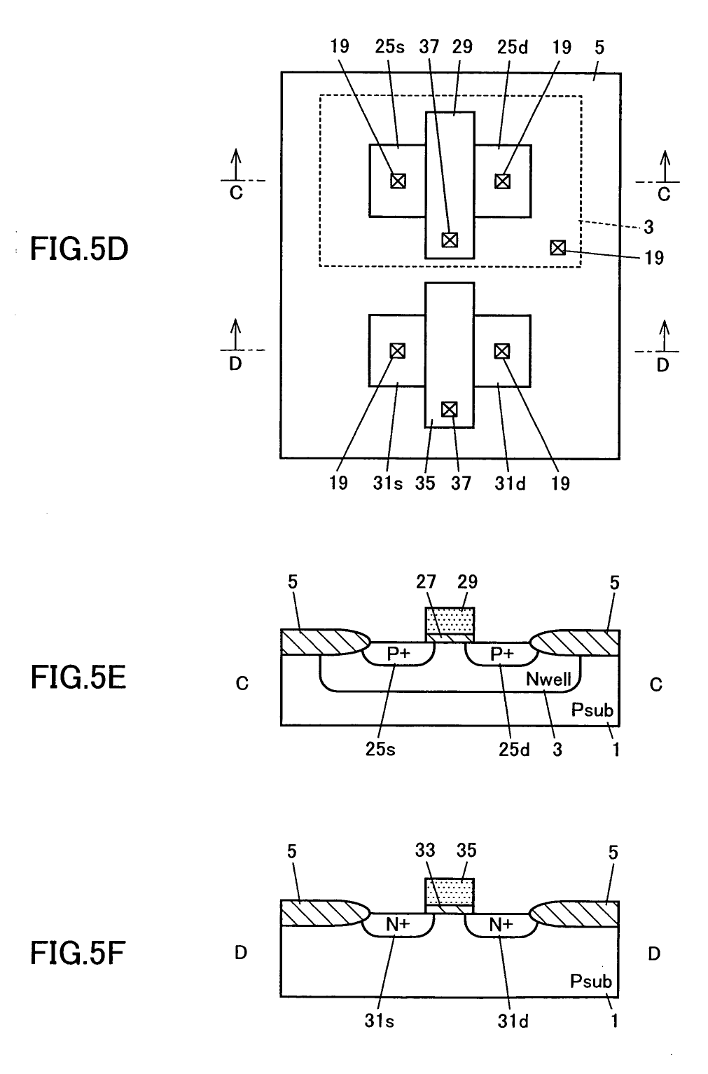

FIG. 5A is a plan view showing a non-volatile memory cell according to still another embodiment of the present invention. FIG. 5B is a cross-sectional view taken along line A-A of FIG. 5A. FIG. 5C is a cross-sectional view taken along line B-B of FIG. 5A. FIG. 5D is a plan view showing peripheral circuit transistors. FIG. 5E is a cross-sectional view taken along line C-C of FIG. 5D. FIG. 5F is a cross-sectional view taken along line D-D of FIG. 5D. In FIGS. 5A-5F, elements having the same functions as the elements in FIGS. 4A-4F are denoted by the same reference numerals. This embodiment is described below with reference to FIGS. 5A-5F.

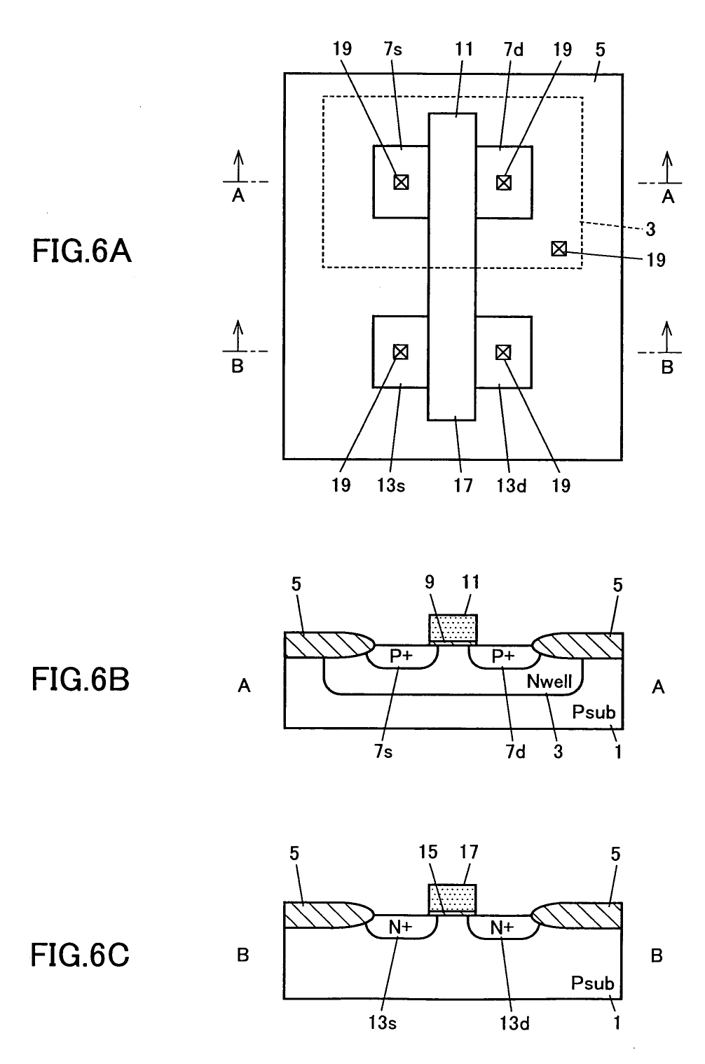

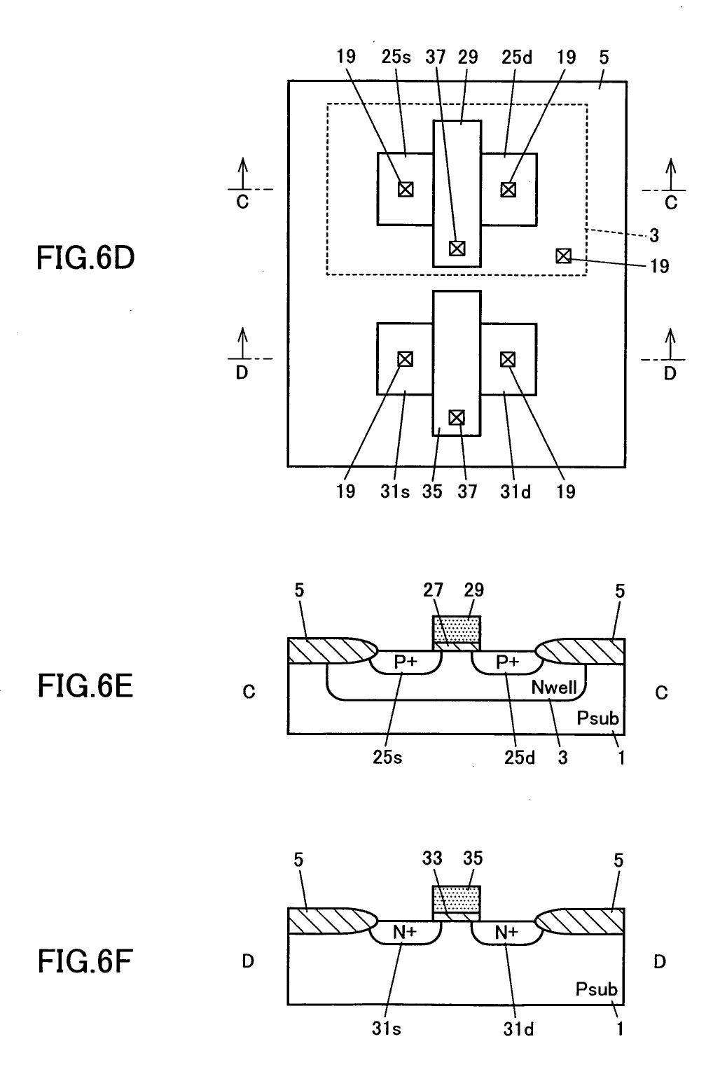

In this embodiment, a write memory gate oxide film 9 and a read memory gate oxide film 15 are thinner (e.g., 7.5 nm thick) than the peripheral circuit gate oxide films 27, 33. A manufacturing method that forms gate oxide films of different thicknesses in multiple MOS transistors on a single semiconductor substrate C of FIG. 6D. FIG. 6F is a cross-sectional view taken along line D-D of FIG. 6D. In FIGS. 6A-6F, elements having the same functions as the elements in FIGS. 5A-5F are denoted by the same reference numerals. This embodiment is described below with reference to FIGS. 6A-6F.

In this embodiment, N-type impurities such as phosphorous are implanted at high concentration in polysilicon in the peripheral circuit gates 29, 35. The substantial concentration of phosphorous in polysilicon in the peripheral circuit gates 29, 35 is, e.g., 1.0×10²⁰ atoms/cm³ or greater, which is higher than the substantial concentration (7.0×10¹⁸ through 5.0×10¹⁹ atoms/cm³) of phosphorous in polysilicon in the write floating gate 11 and the read floating gate 17. A manufacturing method that forms gates having different substantial concentrations of impurities in polysilicon in multiple MOS transistors on a single semiconductor substrate is disclosed in Patent Document 5, for example.

With the above described-configuration, it is possible to improve the charge holding characteristics of the write floating gate 11 and the read floating gate 17, and to sufficiently reduce the resistance of the peripheral circuit gates 29, 35, thereby preventing reduction in the operating speed of the peripheral circuit transistors.

This configuration, in which the substantial concentration of impurities in polysilicon in the peripheral circuit gates 29, is higher than the substantial concentration of impurities in polysilicon in the write floating gate 11 and the read floating gate 17, is applicable to the embodiment shown in FIG. 4A-4F.

Although the substantial concentration of impurities in polysilicon in the write floating gate 11 and the read floating gate 17 may be set equal to the substantial concentration of impurities in polysilicon in the peripheral circuit gates 29, 35 having sufficiently reduced resistance, it is known that such a configuration reduces the charge holding characteristics of the non-volatile memory cell.

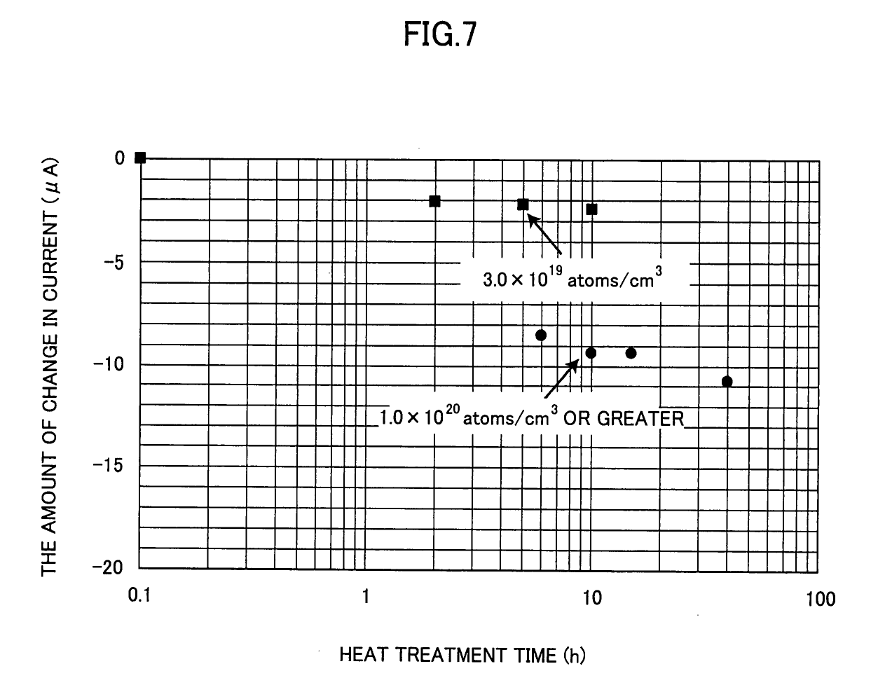

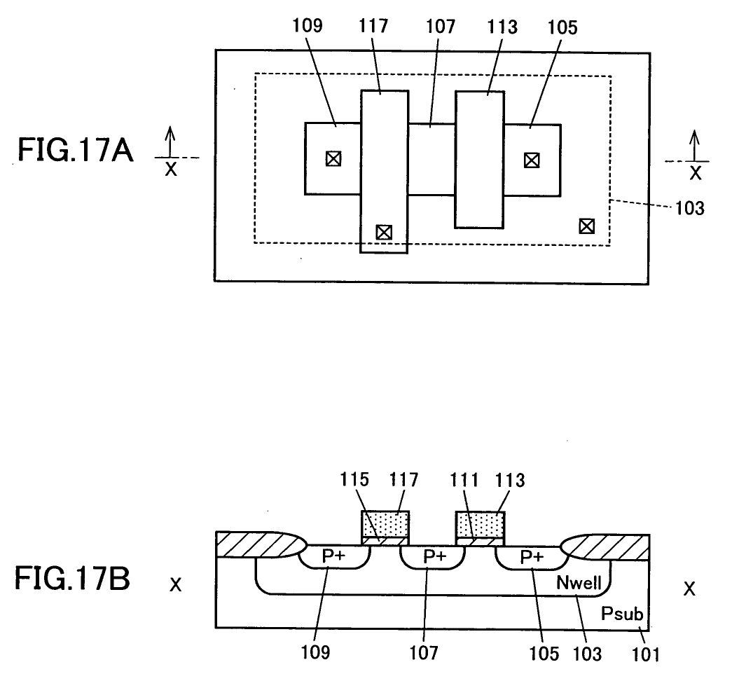

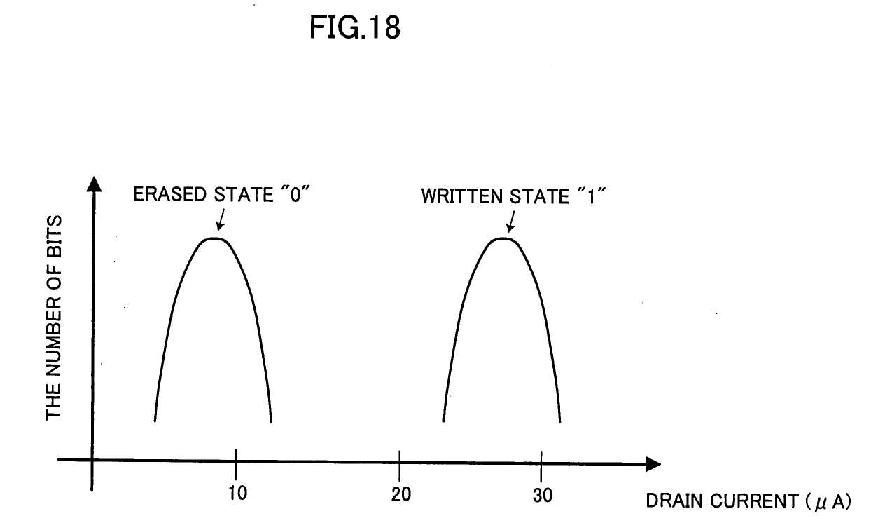

The inventor of the present invention measured the charge holding characteristics of the non-volatile memory cell of the semiconductor device of Patent Document 4. FIG. 7 is a graph showing the measurement results. The vertical axis represents the amount of change in current (μA) and the horizontal axis represents elapsed time (h). The heating temperature was 250° C. Referring also to FIG. 17, a sample in which the substantial phosphorous concentration in a floating gate 113 is 3.0×10¹⁹ atoms/cm³ and a sample in which the substantial phosphorous concentration in a floating gate 113 is 1.0×10²⁰ atoms/cm³ or greater were used as samples. Ion injection was used for implanting phosphorous to prepare the sample of 3.0×10¹⁹ atoms/cm³ phosphorous concentration. On the other hand, deposition and thermal diffusion of phosphorous were used to prepare the sample of 1.0×10²⁰ atoms/cm³ or greater phosphorous concentration.

As electrons that are injected in the floating gate 113 by writing in the non-volatile memory cell leak out over time, the current decreases. That is, the smaller the amount of change in current with time, the higher the charge holding characteristics.

The results shown in FIG. 7 suggest that the sample having lower phosphorous concentration in the floating gate 113 has higher charge holding characteristics.

Accordingly, in the non-volatile memory cell (see FIGS. 6A-6F), in order to improve the charge holding characteristics of the write floating gate 11 and the read floating gate 17, it is preferable that the write floating gate 11 and the read floating gate 17 have a lower substantial impurity concentration than the substantial impurity concentration of the peripheral circuit gates 29, 35.

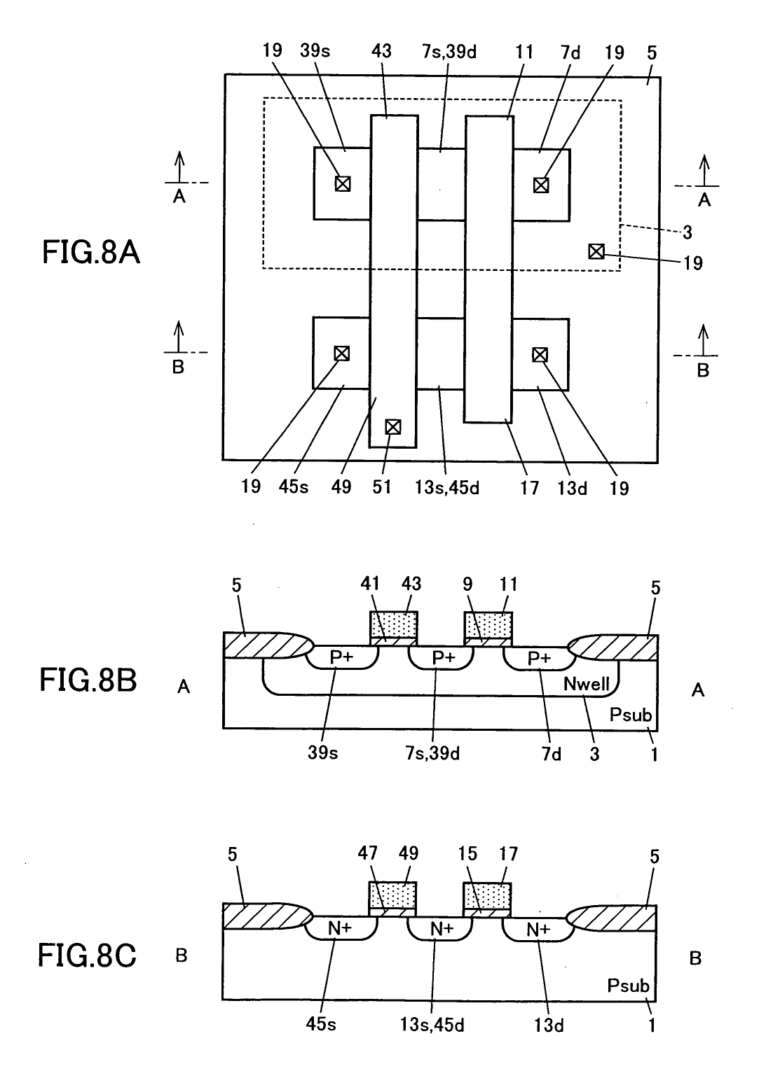

FIG. 8A is a plan view showing a non-volatile memory cell according to still another embodiment of the present invention. FIG. 8B is a cross-sectional view taken along line A-A of FIG. 8A. FIG. 8C is a cross-sectional view taken along line B-B of FIG. 8A. In FIGS. 8A-8C, elements having the same functions as the elements in FIGS. 1A-1C are denoted by the same reference numerals. This embodiment is described below with reference to FIGS. 8A-8C.

In this embodiment, the non-volatile memory cell includes a PMOS write transistor, an NMOS read transistor, a PMOS selection transistor, and an NMOS selection transistor.

The field oxide film 5 includes openings defining a PMOS write transistor region, an NMOS read transistor region, a PMOS selection transistor region, and an NMOS selection transistor region. In this embodiment, the PMOS write transistor region and the PMOS selection transistor region are defined by one of the openings, and the NMOS read transistor region and the NMOS selection transistor region are defined by the other one of the openings.

In a region surrounded by the field oxide film 5 as the PMOS write transistor region and the PMOS selection transistor region, a P-type source 7s, a P-type drain 7d of the PMOS write transistor and a P-type source 39s of the PMOS selection transistor are formed at the surface of an N-well 3. The P-type source 7s and the P-type drain 7d are spaced apart from each other. The P-type source 39s is disposed spaced apart from the P-type source 7s at the side opposite to the side of the P-type drain 7d relative to the P-type source 7s. The P-type source 7s serves also as a P-type drain 39d of the PMOS selection transistor.

A write memory gate oxide film 9 is formed on the N-well 3 between the P-type source 7s and the P-type drain 7d. A write floating gate 11 of polysilicon is formed on the write memory gate oxide film 9. The write memory gate oxide film 9 and the write floating gate 11 partially overlap the P-type source 7s and the P-type drain 7d when viewed from the top. The PMOS write transistor is formed in this way.

A PMOS selection gate oxide film 41 is formed on the N-well 3 between the P-type source 39s and the P-type drain 39d (P-type source 7s). A PMOS selection gate 43 of polysilicon is formed on the PMOS selection gate oxide film 41. The PMOS selection gate oxide film 41 and the PMOS selection gate 43 partially overlap the P-type source 39s and the P-type drain 39d when viewed from the top. The PMOS selection transistor is formed in this way.

A threshold voltage Vth of the PMOS write transistor and the PMOS selection transistor is set to be in the range, for example, about 0.6-0.9 V absolute value by doping channels with P-type impurities.

The PMOS write transistor and the PMOS selection transistor are connected in series by sharing a single P-type diffusion layer forming the P-type source 7s and the P-type drain 39d.

In a region surrounded by the field oxide film 5 as the NMOS read transistor region and the NMOS selection transistor region, an N-type source 13s, an N-type drain 13d, and an N-type source 45s are formed at the surface of the P-type semiconductor substrate 1. The N-type source 13s and the N-type drain 13d formed of diffusion layers are disposed spaced apart from each other. The N-type source 45s of the NMOS selection transistor is disposed spaced apart from the N-type source 13s at the side opposite to the side of the N-type drain 13d relative to the N-type source 13s. The N-type source 13s serves also as an N-type drain 45d of the NMOS selection transistor.

A read memory gate oxide film 15 is formed on the P-type semiconductor substrate 1 between the N-type source 13s and the N-type drain 13d. A read floating gate 17 of polysilicon is formed on the read memory gate oxide film 15. The read memory gate oxide film 15 and the read floating gate 17 partially overlap the N-type source 13s and the N-type drain 13d when viewed from the top. The NMOS read transistor is formed in this way.

An NMOS selection gate oxide film 47 is formed on the P-type semiconductor substrate 1 between the N-type source 45s and the N-type drain 45d (N-type source 13s). An NMOS selection gate 49 of polysilicon is formed on the NMOS selection gate oxide film 47. The NMOS selection gate oxide film 47 and the NMOS selection gate 49 partially overlap the N-type source 45s and the N-type drain 45d when viewed from the top. The NMOS selection transistor is formed in this way.

A threshold voltage Vth of the NMOS read transistor and the NMOS selection transistor is set to be in the range, for example, about 0.6-0.9 V absolute value by doping channels with P-type impurities.

The NMOS read transistor and the NMOS selection transistor are connected in series by sharing a single P-type diffusion layer forming the N-type source 13s and the N-type drain 45d.

The write memory gate oxide film 9, the read memory gate oxide film 15, the PMOS selection gate oxide film 41, and the NMOS selection gate oxide film 47 are formed all at once, and their thickness is, for example, in the range 7.5-15.0 nm (in this example, 13.5 nm).

The P-type drain 7d, the P-type source 39s, the N-type drain 13d, and the N-type source 45s are connected to corresponding contacts 19. The field oxide film 5 further includes an opening for obtaining a potential of the N-well 3, through which opening a corresponding contact 19 is connected to the N-well 3.

The write floating gate 11 and the read floating gate 17 are formed of a single electrically-floating continuous polysilicon pattern extending on the field oxide film 5. The PMOS selection gate 43 and the NMOS selection gate 49 are formed of a single continuous polysilicon pattern extending on the field oxide film 5. A contact 51 is formed on the polysilicon pattern forming the PMOS selection gate 43 and the NMOS selection gate 49.

The polysilicon pattern forming the write floating gate 11 and the read floating gate 17 and the polysilicon pattern forming the PMOS selection gate 43 and the NMOS selection gate 49 are formed all at once, and their thickness is, for example, in the range 250-450 nm (in this example, 350 nm). N-type impurities such as phosphorous are implanted in these polysilicon patterns. The substantial concentration of phosphorous is in the range, for example, from 7.0×10¹⁸ to 5.0×10¹⁹ atoms/cm³.

In the non-volatile memory cell of this embodiment, to establish an erased state “0”, erasure using ultraviolet rays is performed on the PMOS write transistor and the NMOS read transistor, thereby removing charges from the write floating gate 11 and the read floating gate 17.

To establish a written state “1”, 0 V is applied to the P-type drain 7d of the PMOS write transistor; a predetermined potential Von (e.g., 0 V) is applied to the PMOS selection gate 43; and Vpp (e.g., 7 V) is applied to the P-type source 39s of the PMOS selection transistor and the N-well 3 for a period of time ranging from several microseconds to several hundred microseconds. Thus the PMOS selection transistor is turned on, and electrons are injected into the floating gate 113. At this point, electrons are also injected into the read floating gate 17 via the write floating gate 11, so that the threshold voltage Vth of the NMOS read transistor is increased to, e.g., 3-5 V, compared with the erased state “0”.

For reading from the non-volatile memory cells, 2 V is applied to the N-type drain 13d of the NMOS read transistor; 0 V is applied to the N-type source 45s; and 5V to the NMOS selection gate 49 such that the NMOS selection transistor can be turned on.

In the written state “1”, because the threshold voltage of the NMOS read transistor is in the range about 3-5 V due to injection of the write floating gate 11 and the read floating gate 17, little or no current flows through the NMOS read transistor.

In the erased state “0”, because the threshold voltage of the NMOS read transistor is in the range about 0.6-0.9 V, a current in the range about 10-20 μA flows through the NMOS read transistor.

In this way, it is possible to read out information stored in the non-volatile memory cell by applying appropriate voltages to the N-type source 45s and the NMOS selection gate 49 of the non-volatile memory cell.

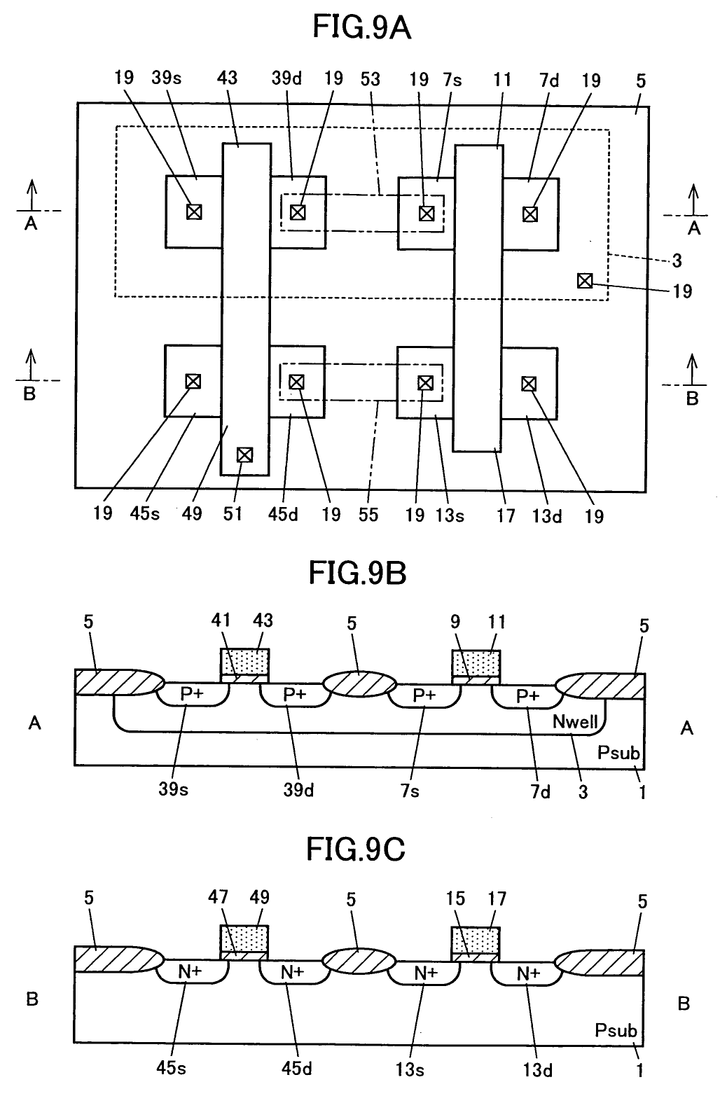

FIG. 9A is a plan view showing a non-volatile memory cell according to still another embodiment of the present invention. FIG. 9B is a cross-sectional view taken along line A-A of FIG. 9A. FIG. 9C is a cross-sectional view taken along line B-B of FIG. 9A. In FIGS. 9A-9C, elements having the same functions as the elements in FIGS. 8A-BC are denoted by the same reference numerals. This embodiment is described below with reference to FIGS. 9A-9C.

In this embodiment, a PMOS write transistor region, a PMOS selection transistor region, an NMOS read transistor region, and an NMOS selection transistor region are separated from each other by a field oxide film 5.

A P-type source 7s of a PMOS write transistor and a P-type drain 39d of a PMOS selection transistor are connected to each other via corresponding contacts 19, 19 and a metal interconnect 53, so that the PMOS write transistor and the PMOS selection transistor are connected in series.

A N-type source 13s of an NMOS read transistor and an N-type drain 45d of an NMOS selection transistor are connected to each other via corresponding contacts 19, 19 and a metal interconnect 55, so that the NMOS read transistor and the NMOS selection transistor are connected in series.

In this way, the PMOS write transistor region, the PMOS selection transistor region, the NMOS read transistor region, and the NMOS selection transistor region may be separated from each other by the field oxide film 5. However, the configuration shown in FIGS. 8A-8C, in which the PMOS write transistor and the PMOS selection transistor share the P-type diffusion layer forming the P-type source 7s and the P-type drain 39d while the NMOS read transistor and the NMOS selection transistor share the single P-type diffusion layer forming the N-type source 13s and the N-type drain 45d, is advantageous in terms of area efficiency.

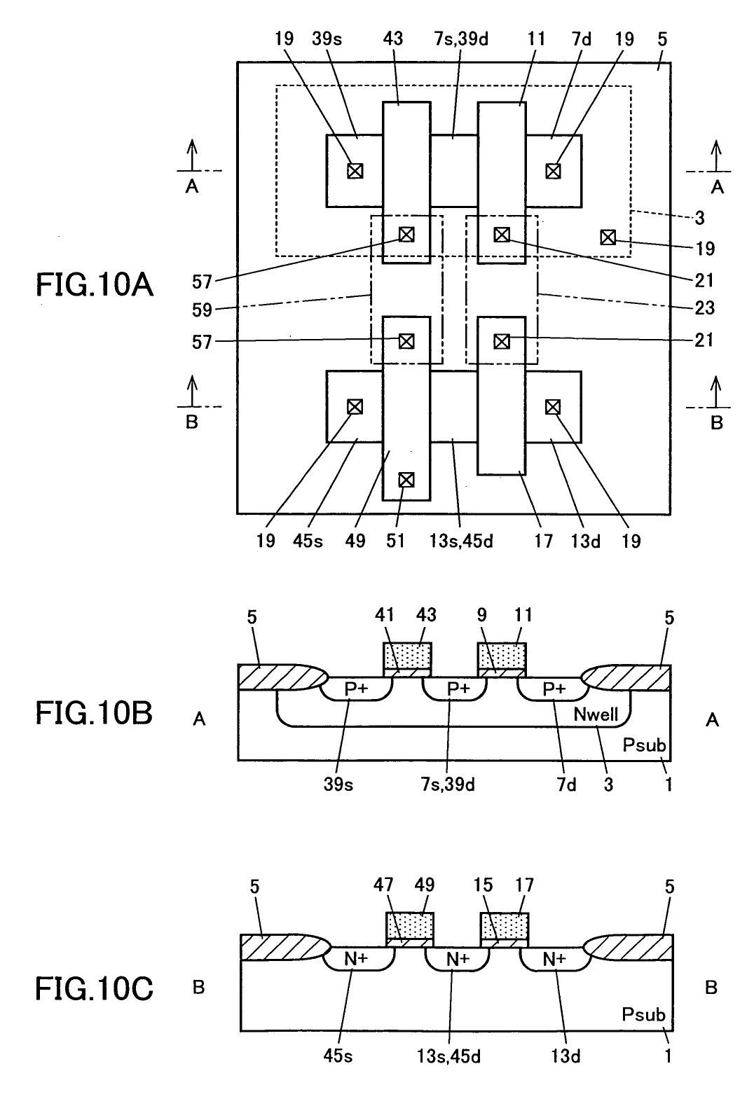

FIG. 10A is a plan view showing a non-volatile memory cell according to still another embodiment of the present invention. FIG. 10B is a cross-sectional view taken along line A-A of FIG. 10A. FIG. 10C is a cross-sectional view taken along line B-B of FIG. 10A. In FIGS. 10A-10C, elements having the same functions as the elements in FIGS. 8A-BC are denoted by the same reference numerals. This embodiment is described below with reference to FIGS. 10A-10C.

The non-volatile memory cell of this embodiment is different from the non-volatile memory cell of FIGS. 8A-8C in that (1) a write floating gate 11 and read floating gate 17 are formed of separate polysilicon patterns and are disposed spaced apart from each other as in the embodiment shown in FIGS. 3A-3C, and that (2) a PMOS selection gate 43 and an NMOS selection gate 49 are formed of formed of separate polysilicon patterns and are disposed spaced apart from each other.

The write floating gate 11 and the read floating gate 17 are electrically connected to each other via corresponding contacts 21, 21 and a metal interconnect 23. The PMOS selection gate 43 and the NMOS selection gate 49 are electrically connected to each other via corresponding contacts 57, 57 and a metal interconnect 59.

In this way, the write floating gate 11 and the read floating gate 17 do not have to be formed of a single continuous polysilicon pattern. Similarly, the PMOS selection gate 43 and the NMOS selection gate 49 do not have to be formed of a single continuous polysilicon pattern.

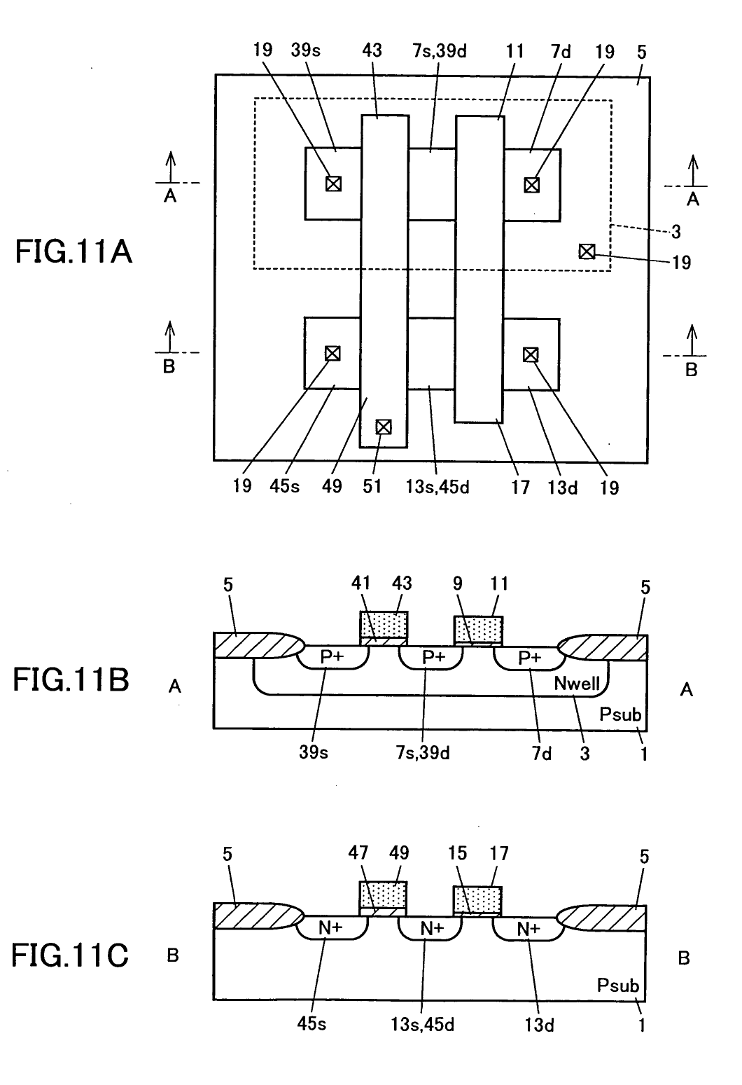

FIG. 11A is a plan view showing a non-volatile memory cell according to still another embodiment of the present invention. FIG. 11B is a cross-sectional view taken along line A-A of FIG. 11A. FIG. 11C is a cross-sectional view taken along line B-B of FIG. 11A. In FIGS. 11A-11C, elements having the same functions as the elements in FIGS. 8A-BC are denoted by the same reference numerals. This embodiment is described below with reference to FIGS. 11A-11C.

In this embodiment, a write memory gate oxide film 9 and a read memory gate oxide film 15 are thinner (e.g., 7.5 nm thick) than a PMOS selection gate oxide film 41 and an NMOS selection gate oxide film 47.

Because the write memory gate oxide film 9 is thinner than that in the embodiment of FIGS. 8A-8C, writing can be performed at a low voltage in the range, for example, about 5-7 V.

In this way, the PMOS selection gate oxide film 41 has a greater thickness to not be damaged upon writing in the memory cell, while the write memory gate oxide film 9 has a reduced thickness to improve the writing characteristics of the non-volatile memory cell. It is therefore possible to properly write in the non-volatile memory cell while preventing the PMOS selection gate oxide film 41 from being damaged and preventing occurrence of snapback breakdown.

It is to be noted that the NMOS selection gate oxide film 47 may have the same thickness as the thickness of the write memory gate oxide film 9 and the read memory gate oxide film 15.

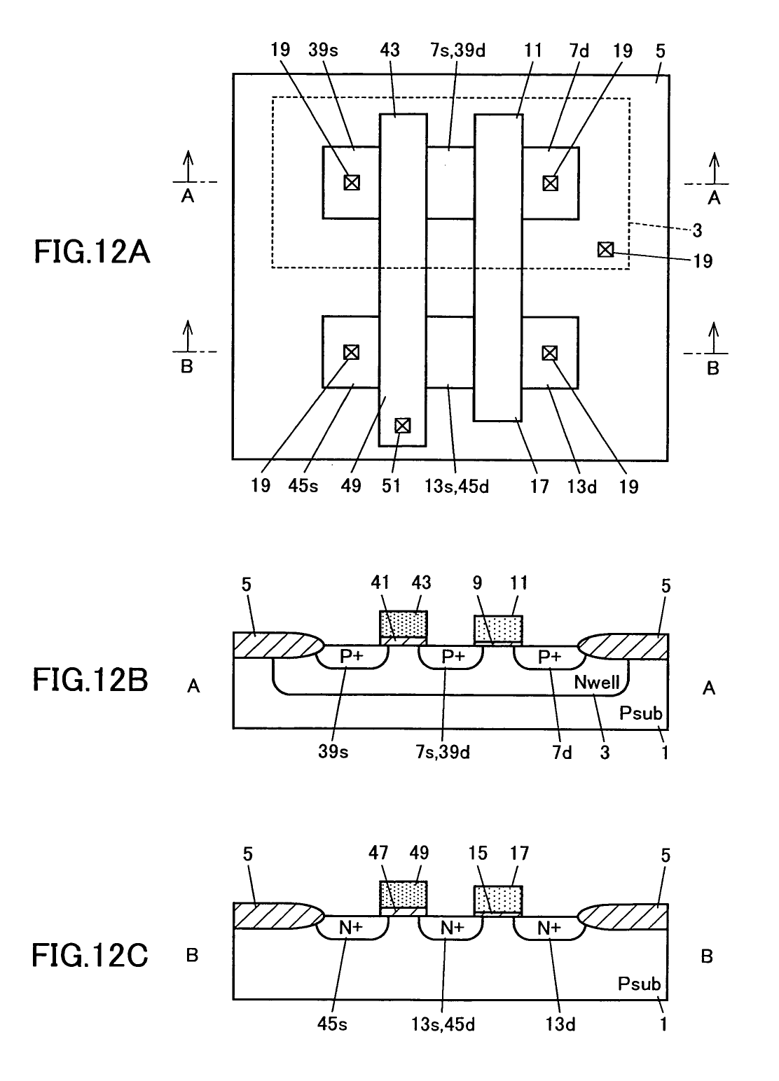

FIG. 12A is a plan view showing a non-volatile memory cell according to still another embodiment of the present invention. FIG. 12B is a cross-sectional view taken along line A-A of FIG. 12A. FIG. 12C is a cross-sectional view taken along line B-B of FIG. 12A. In FIGS. 12A-12C, elements having the same functions as the elements in FIGS. 11A-11C are denoted by the same reference numerals. This embodiment is described below with reference to FIGS. 12A-12C.

In this embodiment, N-type impurities such as phosphorous are implanted at high concentration in polysilicon in a PMOS selection gate 43 and an NMOS selection gate 49. The substantial concentration of phosphorous in polysilicon in the PMOS selection gate 43 and the NMOS selection gate 49 is, e.g., 1.0×10²⁰ atoms/cm³ or greater, which is higher than the substantial concentration (7.0×10¹⁸ through 5.0×10¹⁹ atoms/cm³) of phosphorous in polysilicon in a write floating gate 11 and a read floating gate 17.

With this configuration, it is possible to improve the charge holding characteristics of the write floating gate 11 and the read floating gate 17, and to sufficiently reduce the resistance of the PMOS selection gate 43 and the NMOS selection gate 49, thereby preventing reduction in the operating speed of a PMOS selection transistor and an NMOS selection transistor.

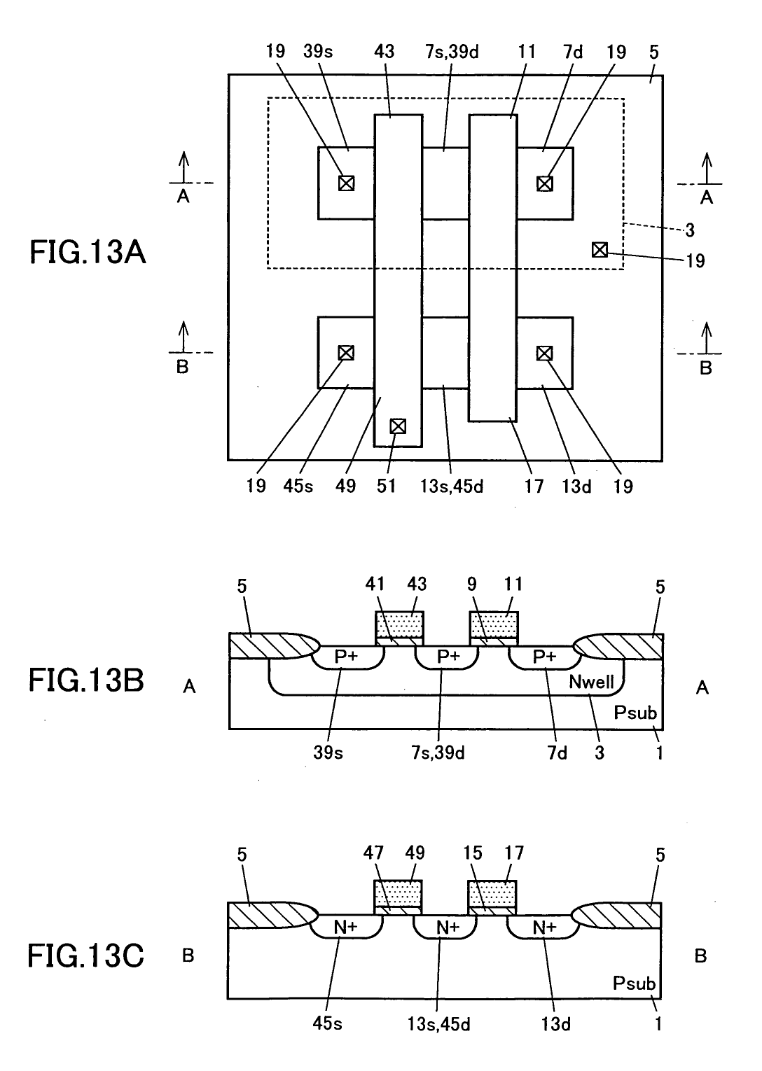

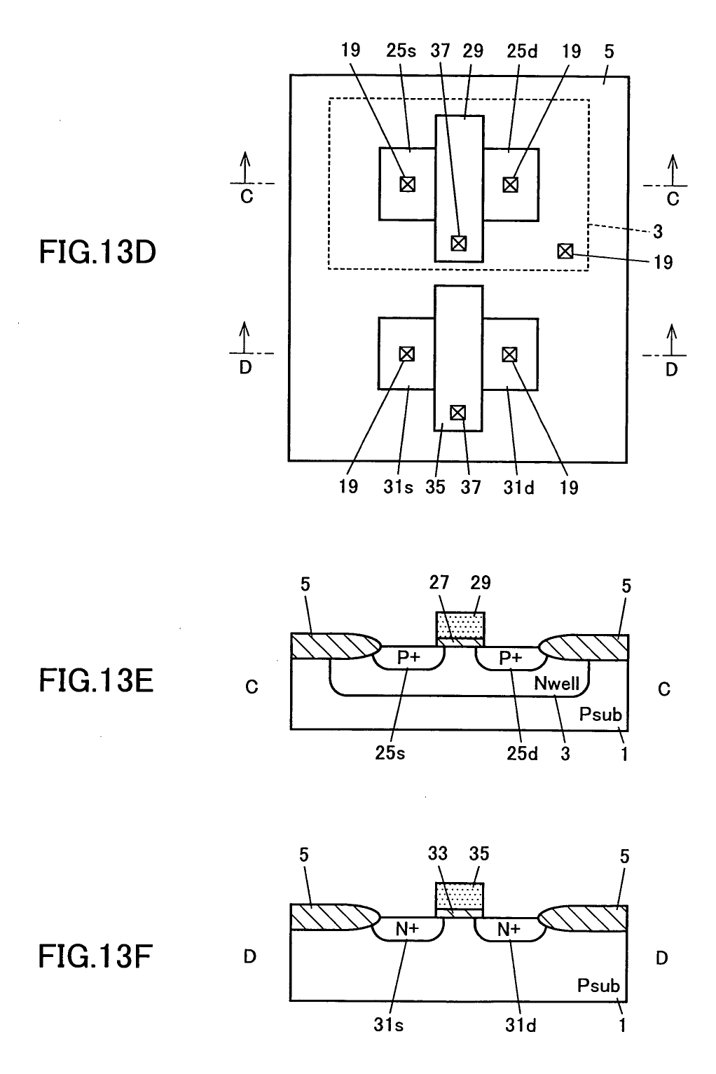

FIG. 13A is a plan view showing a non-volatile memory cell according to still another embodiment of the present invention. FIG. 13B is a cross-sectional view taken along line A-A of FIG. 13A. FIG. 13C is a cross-sectional view taken along line B-B of FIG. 13A. FIG. 13D is a plan view showing peripheral circuit transistors.

FIG. 13E is a cross-sectional view taken along line C-C of FIG. 13D. FIG. 13F is a cross-sectional view taken along line D-D of FIG. 13D. In FIGS. 13A-13F, elements having the same functions as the elements in FIGS. 8A-8F are denoted by the same reference numerals. This embodiment is described below with reference to FIGS. 13A-13F.

In this embodiment, as in the embodiment shown in FIGS. 4A-4F, a PMOS peripheral circuit transistor and an NMOS peripheral circuit transistor are disposed in positions different from the position of a non-volatile memory cell on a P-type semiconductor substrate 1.

The configurations of the PMOS peripheral circuit transistor and the NMOS peripheral circuit transistor are the same as those in the embodiment of FIGS. 4A-4F and are therefore not described herein.

A write memory gate oxide film 9, a read memory gate oxide film 15, a PMOS selection gate oxide film 41, an NMOS selection gate oxide film 47, and peripheral circuit gate oxide films 27, 33 are formed all at once, and their thickness is, for example, in the range 7.5-15.0 nm (in this example, 13.5 nm).

A write floating gate 11, a read floating gate 17, a PMOS selection gate 43, a NMOS selection gate 49, and a peripheral circuit gates 29, 35 are formed all at once, and their thickness is, for example, in the range 250-450 nm (in this example, 350 nm). N-type impurities such as phosphorous are implanted in the gates 11, 17, 29, 35, 43 and 49. The substantial concentration of phosphorous is in the range, for example, from 7.0×10¹⁸ to 5.0×10¹⁹ atoms/cm³.

A threshold voltage Vth of a PMOS write transistor, a PMOS selection transistor, and the PMOS peripheral circuit transistor is set to be in the range, for example, about 0.6-0.9 V absolute value by doping channels with P-type impurities.

A threshold voltage Vth of an NMOS read transistor, an NMOS selection transistor, and the NMOS peripheral circuit transistor is set to be in the range, for example, about 0.6-0.9 V absolute value by doping channels with P-type impurities.

In this embodiment, the write memory gate oxide film 9, the read memory gate oxide film 15, the PMOS selection gate oxide film 41, the NMOS selection gate oxide film 47, and the peripheral circuit gate oxide films 27, 33 are formed all at once. Therefore, the number of manufacturing steps can be reduced compared with the case where these gate oxide films are formed in separate steps.

Further, the write floating gate 11, the read floating gate 17, the PMOS selection gate 43, the NMOS selection gate 49, and the peripheral circuit gates 29, 35 are formed all at once. Therefore, the number of manufacturing steps can be reduced compared with the case where these gates are formed in separate steps.

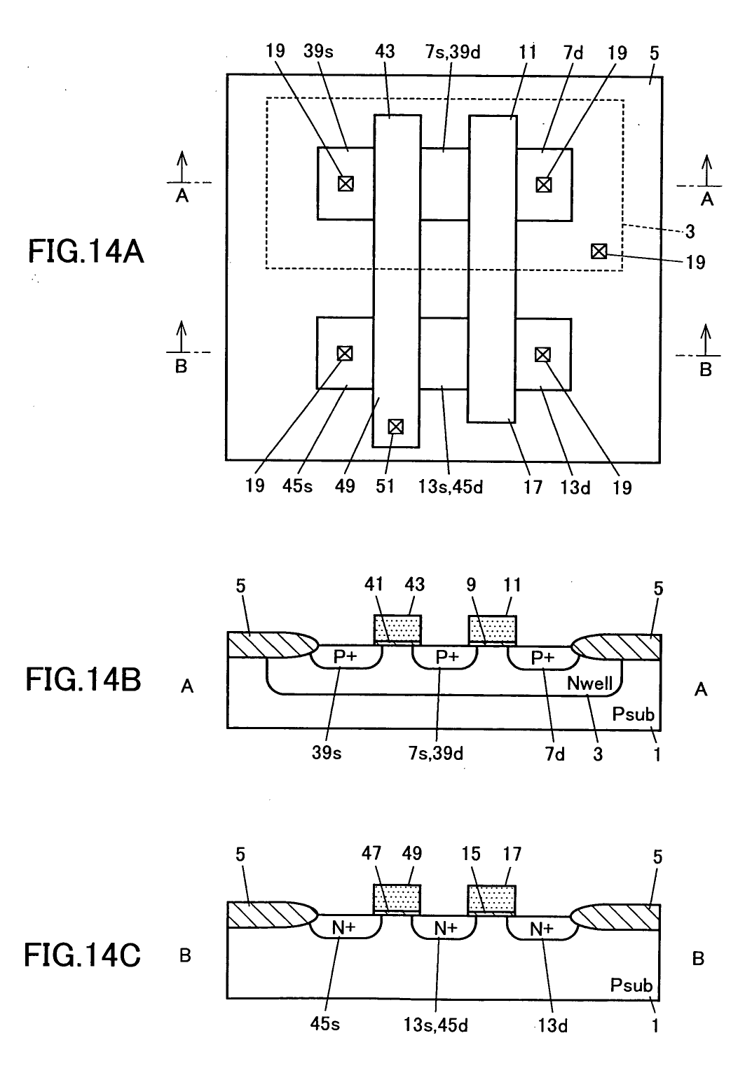

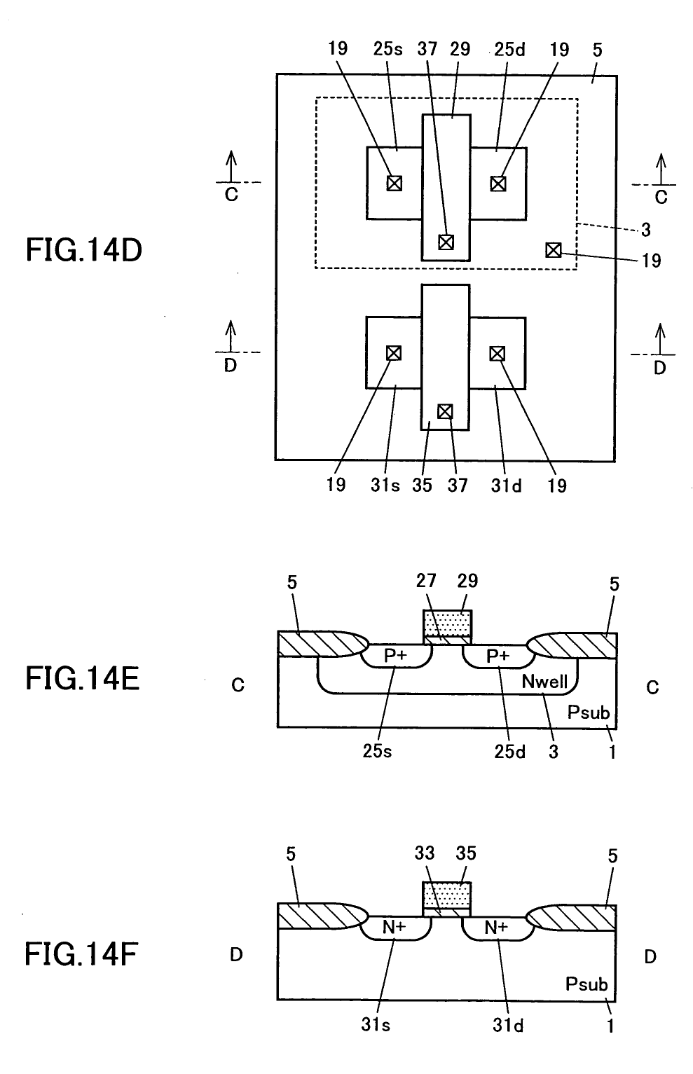

FIG. 14A is a plan view showing a non-volatile memory cell according to still another embodiment of the present invention. FIG. 14B is a cross-sectional view taken along line A-A of FIG. 14A. FIG. 14C is a cross-sectional view taken along line B-B of FIG. 14A. FIG. 14D is a plan view showing peripheral circuit transistors.

FIG. 14E is a cross-sectional view taken along line C-C of FIG. 14D. FIG. 14F is a cross-sectional view taken along line D-D of FIG. 14D. In FIGS. 14A-14F, elements having the same functions as the elements in FIGS. 13A-13F are denoted by the same reference numerals. This embodiment is described below with reference to FIGS. 14A-14F.

In this embodiment, a write memory gate oxide film 9, a read memory gate oxide film 15, a PMOS selection gate oxide film 41, and an NMOS selection gate oxide film 47 are thinner (e.g., 7.5 nm thick) than peripheral circuit gate oxide films 27, 33.

Because the write memory gate oxide film 9 is thinner than that in the embodiment of FIGS. 8A-8C, writing can be performed at a low voltage in the range, for example, about 5-7 V.

In this way, the peripheral circuit gate oxide films 27, 33 have greater thickness to not be damaged upon writing in the memory cell, while the write memory gate oxide film 9 has a reduced thickness to improve the writing characteristics of the non-volatile memory cell.

It is therefore possible to properly write in the non-volatile memory cell while preventing the peripheral circuit gate oxide films 27, 33 from being damaged and preventing occurrence of snapback breakdown.

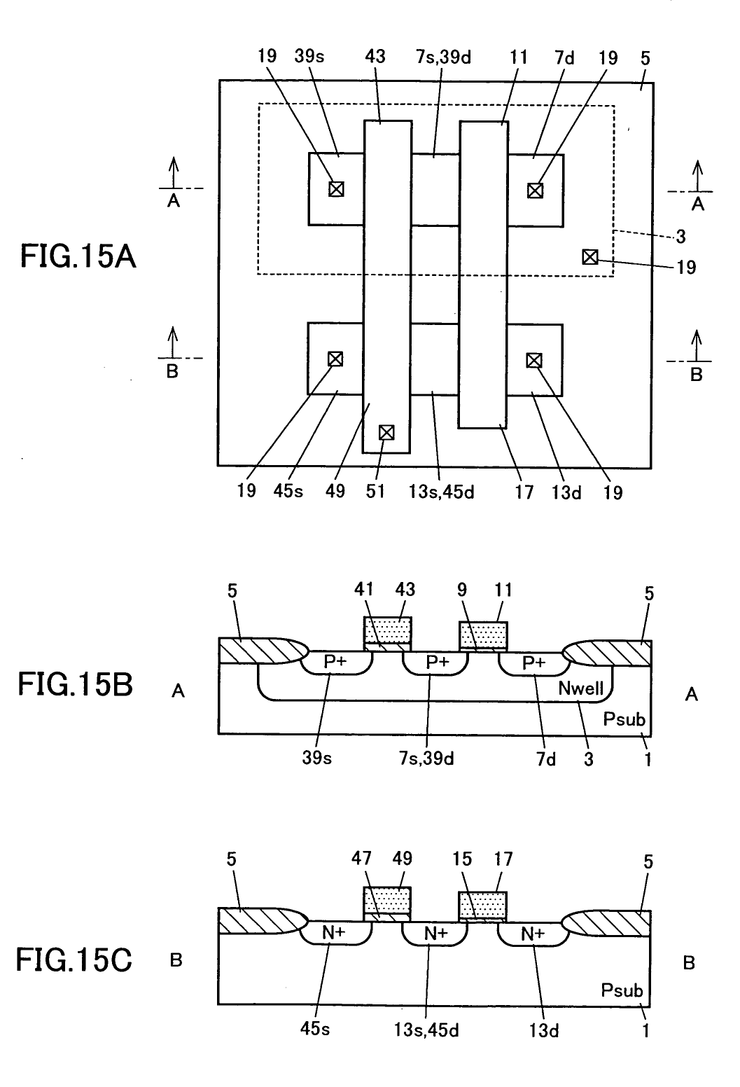

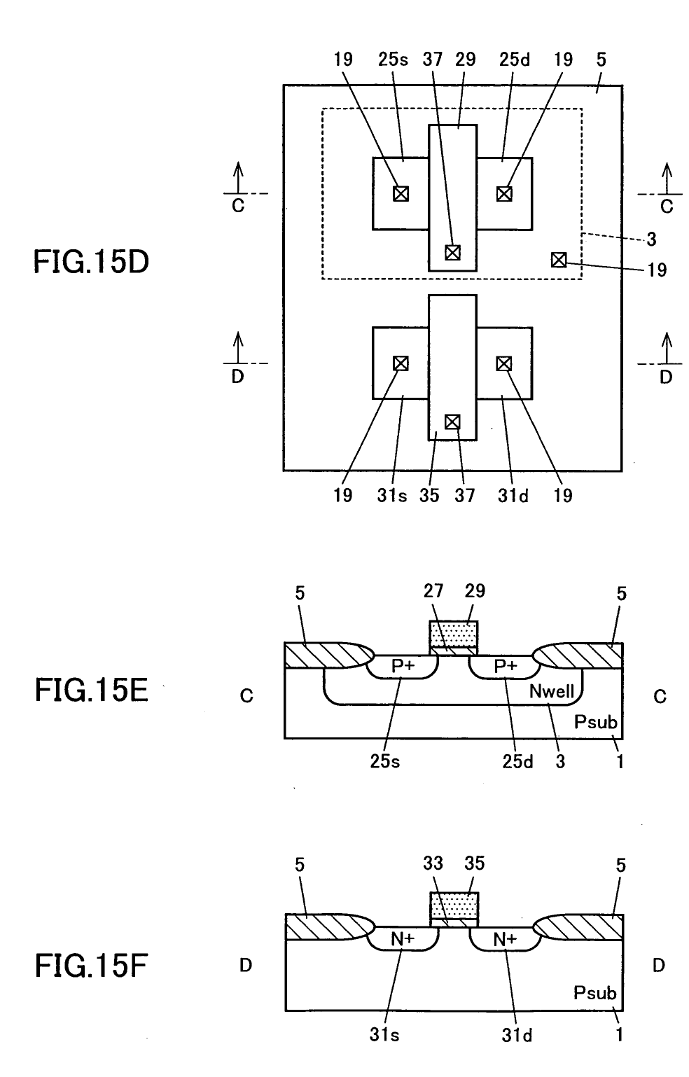

FIG. 15A is a plan view showing a non-volatile memory cell according to still another embodiment of the present invention. FIG. 15B is a cross-sectional view taken along line A-A of FIG. 15A. FIG. 15C is a cross-sectional view taken along line B-B of FIG. 15A. FIG. 15D is a plan view showing peripheral circuit transistors.

FIG. 15E is a cross-sectional view taken along line C-C of FIG. 15D. FIG. 15F is a cross-sectional view taken along line D-D of FIG. 15D. In FIGS. 15A-15F, elements having the same functions as the elements in FIGS. 13A-13F are denoted by the same reference numerals. This embodiment is described below with reference to FIGS. 15A-15F.

In this embodiment, a PMOS selection gate oxide film 41 and an NMOS selection gate oxide film 47 are formed at the same time as peripheral circuit gate oxide films 27, 33, and have the same thickness as the peripheral circuit gate oxide films 27, 33.

With this configuration, it is therefore possible to prevent the PMOS selection gate oxide film 41 from being damaged when writing in the non-volatile memory cell and to prevent occurrence of snapback breakdown.

It is to be noted that the NMOS selection gate oxide film 47 may have the same thickness as the thickness of the write memory gate oxide film 9 and the read memory gate oxide film 15.

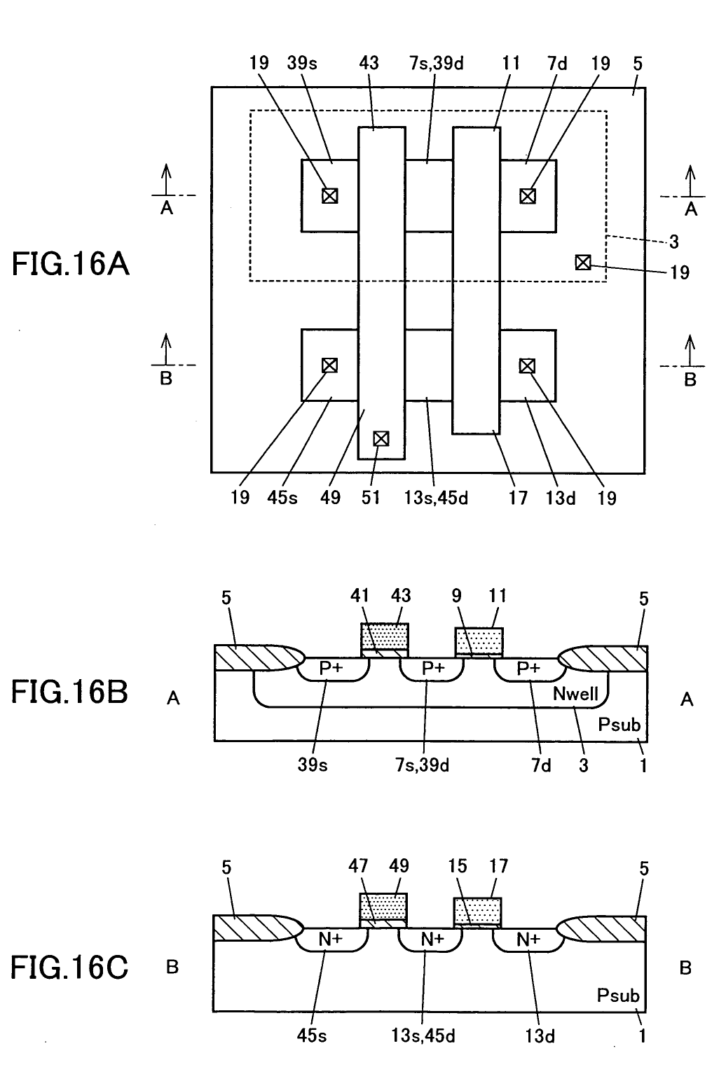

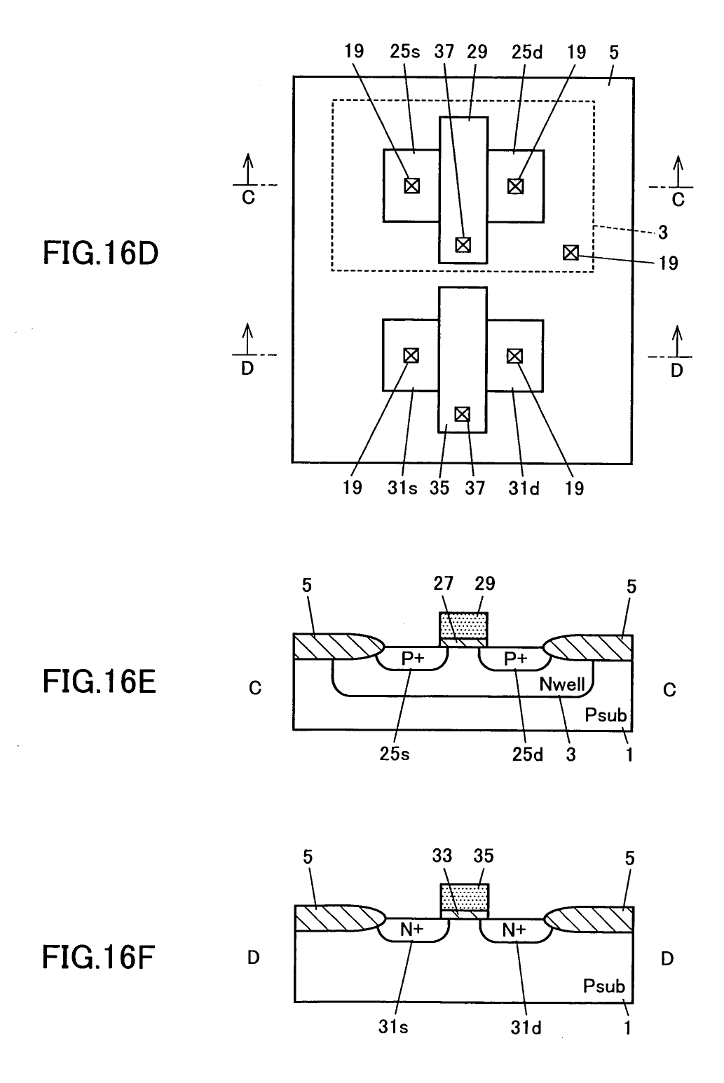

FIG. 16A is a plan view showing a non-volatile memory cell according to still another embodiment of the present invention. FIG. 16B is a cross-sectional view taken along line A-A of FIG. 16A. FIG. 16C is a cross-sectional view taken along line B-B of FIG. 16A. FIG. 16D is a plan view showing peripheral circuit transistors.

FIG. 16E is a cross-sectional view taken along line C-C of FIG. 16D. FIG. 16F is a cross-sectional view taken along line D-D of FIG. 16D. In FIGS. 16A-16F, elements having the same functions as the elements in FIGS. 16A-16F are denoted by the same reference numerals. This embodiment is described below with reference to FIGS. 16A-16F.

In this embodiment, N-type impurities such as phosphorous are implanted at high concentration in polysilicon in a PMOS selection gate 43, an NMOS selection gate 49, and peripheral circuit gates 29, 35. The substantial concentration of phosphorous in polysilicon in the PMOS selection gate 43, the NMOS selection gate 49, and the peripheral circuit gates 29, 35 is, e.g., 1.0×10²⁰ atoms/cm³ or greater, which is higher than the substantial concentration (7.0×10¹⁸ through 5.0×10¹⁹ atoms/cm³) of phosphorous in polysilicon in a write floating gate 11 and a read floating gate 17.

With this configuration, it is possible to improve the charge holding characteristics of the write floating gate 11 and the read floating gate 17, and to sufficiently reduce the resistance of the PMOS selection gate 43, the NMOS selection gate 49, and the peripheral circuit gates 29, 35, thereby preventing In FIGS. 16A-16F, elements having the same functions as the elements in FIGS. 16A-16F are denoted by the same reference numerals. This embodiment is described below with reference to FIGS. 16A-16F.

In this embodiment, N-type impurities such as phosphorous are implanted at high concentration in polysilicon in a PMOS selection gate 43, an NMOS selection gate 49, and peripheral circuit gates 29, 35. The substantial concentration of phosphorous in polysilicon in the PMOS selection gate 43, the NMOS selection gate 49, and the peripheral circuit gates 29, 35 is, e.g., 1.0×10²⁰ atoms/cm³ or greater, which is higher than the substantial concentration (7.0×10¹⁸ through 5.0×10¹⁹ atoms/cm³) of phosphorous in polysilicon in a write floating gate 11 and a read floating gate 17.

With this configuration, it is possible to improve the charge holding characteristics of the write floating gate 11 and the read floating gate 17, and to sufficiently reduce the resistance of the PMOS selection gate 43, the NMOS selection gate 49, and the peripheral circuit gates 29, 35, thereby preventing reduction in the operating speed of a PMOS selection transistor, an NMOS selection transistor, and peripheral circuit transistors.

This configuration, in which the substantial concentration of impurities in polysilicon in the PMOS selection gate 43, the NMOS selection gate 49, and the peripheral circuit gates 29, 35 is higher than the substantial concentration of impurities in polysilicon in the write floating gate 11 and the read floating gate 17, is applicable to the embodiments of FIGS. 13A-13F, 14A-14F, and 15A-15F.

Alternatively, the substantial impurity concentration of the PMOS selection gate 43 and the NMOS selection gate 49 may be the same as that of the write floating gate 11 and the read floating gate 17 and be lower than that of the peripheral circuit gates 29, 35.

While the present invention has been described in terms of the presently preferred embodiments, the present invention is not limited to these embodiments. It will be apparent to those skilled in the art that various changes may be made in the size, shape, materials, arrangement of elements, and impurity concentration without departing from the scope of the invention as set forth in the accompanying claims.

For example, although a P-type semiconductor substrate is used in the above embodiments, an N-type substrate may alternatively be used.

Although a field oxide film is used as an insulating film for device isolation, an STI (Shallow Trench Isolation) structure may alternatively be used.

Although the write gate oxide film of the PMOS write transistor and the read gate oxide film of the NMOS read transistor in the above embodiments have the same thickness, these gate oxide films may have different thicknesses.

Although the peripheral circuit gate oxide films of the PMOS peripheral circuit transistor and the NMOS peripheral circuit transistor have the same thickness in the embodiments in which peripheral circuit transistors are provided, these gate oxide films may have different thicknesses.

In the embodiments in which a PMOS selection transistor and an NMOS selection transistor are provided, the PMOS selection gate oxide film and the NMOS selection gate oxide film may have the same thickness or different thicknesses.

In the above embodiments in which plural polysilicon patterns are provided to form gates of MOS transistors, the polysilicon patterns may or may not have the same thickness and the same impurity concentration.

The present application is based on Japanese Priority Application No. 2007-143455 filed on May 30, 2007, with the Japanese Patent Office, the entire contents of which are hereby incorporated by reference.

What is claimed is:

1. A semiconductor device, comprising:
a non-volatile memory cell including a PMOS write transistor and an NMOS read transistor;
wherein the PMOS write transistor includes a write memory gate oxide film formed on a semiconductor substrate and a write floating gate of electrically-floating polysilicon formed on the write memory gate oxide film;
wherein the NMOS read transistor includes a read memory gate oxide film formed on the semiconductor substrate and a read floating gate of electrically-floating polysilicon formed on the read memory gate oxide film;
wherein the write floating gate and the read floating gate are electrically connected to each other; and
wherein the PMOS write transistor is configured to perform writing in the non-volatile memory cell, and the NMOS read transistor is configured to perform reading from the non-volatile memory cell.

2. The semiconductor device as claimed in claim 1, wherein the write floating gate and the read floating gate are formed of a single continuous polysilicon pattern.

3. The semiconductor device as claimed in claim 1,
wherein the non-volatile memory cell further includes a PMOS selection transistor connected in series to the PMOS write transistor and an NMOS selection transistor connected in series to the NMOS read transistor;
wherein the PMOS selection transistor includes a PMOS selection gate oxide film formed on the semiconductor substrate and a PMOS selection gate of polysilicon formed on the PMOS selection gate oxide film;
wherein the NMOS selection transistor includes an NMOS selection gate oxide film formed on the semiconductor substrate and an NMOS selection gate of polysilicon formed on the NMOS selection gate oxide film; and
wherein the PMOS selection gate and the NMOS selection gate are electrically connected to each other.

4. The semiconductor device as claimed in claim 3, wherein the PMOS selection gate and the NMOS selection gate are formed of a single continuous polysilicon pattern.

5. The semiconductor device as claimed in claim 3, wherein the write memory gate oxide film, the read memory gate oxide film, the PMOS selection gate oxide film, and the NMOS selection gate oxide film have an equal thickness.

6. The semiconductor device as claimed in claim 3, wherein the write floating gate, the read floating gate, the PMOS selection gate, and the NMOS selection gate have an equal impurity concentration in polysilicon.

7. The semiconductor device as claimed in claim 1, further comprising:
a peripheral circuit transistor formed of a MOS transistor that includes a peripheral circuit gate oxide film formed on the semiconductor substrate and a peripheral circuit gate of polysilicon formed on the peripheral circuit gate oxide film;
wherein a thickness of the write memory gate oxide film is less than a thickness of the peripheral circuit gate oxide film.

8. The semiconductor device as claimed in claim 1, further comprising:
a peripheral circuit transistor formed of a MOS transistor that includes a peripheral circuit gate oxide film formed on the semiconductor substrate and a peripheral circuit gate of polysilicon formed on the peripheral circuit gate oxide film;
wherein impurity concentrations in polysilicon in the write floating gate and the read floating gate are lower than an impurity concentration in polysilicon in the peripheral circuit gate.

9. The semiconductor device as claimed in claim 3, further comprising:
a peripheral circuit transistor formed of a MOS transistor that includes a peripheral circuit gate oxide film formed on the semiconductor substrate and a peripheral circuit gate of polysilicon formed on the peripheral circuit gate oxide film;
wherein a thickness of the write memory gate oxide film is less than a thickness of the peripheral circuit gate oxide film; and
wherein thicknesses of the PMOS selection gate oxide film and the NMOS selection gate oxide film are the same as a thickness of the peripheral circuit gate oxide film.

10. The semiconductor device as claimed in claim 3, further comprising:
a peripheral circuit transistor formed of a MOS transistor that includes a peripheral circuit gate oxide film formed on the semiconductor substrate and a peripheral circuit gate of polysilicon formed on the peripheral circuit gate oxide film;
wherein impurity concentrations in polysilicon in the write floating gate and the read floating gate are lower than an impurity concentration in polysilicon in the peripheral circuit gate; and
wherein impurity concentrations in polysilicon in the PMOS selection gate and the NMOS selection gate are the same as the impurity concentration in polysilicon in the peripheral circuit gate.

11. The semiconductor device as claimed in claim 1, further comprising:
an NMOS peripheral circuit transistor formed of a MOS transistor that includes an NMOS peripheral circuit gate oxide film formed on the semiconductor substrate and a peripheral circuit gate of polysilicon formed on the NMOS peripheral circuit gate oxide film;
wherein a channel of the NMOS peripheral circuit transistor is doped with P-type impurities; and
wherein a channel of the NMOS read transistor is not doped with P-type impurities.

12. The semiconductor device as claimed in claim 1, wherein the NMOS read transistor is in a depletion state in an erased state in which electrons are not injected in the write floating gate and the read floating gate.
